(19) United States
(12) Patent Application Publication
(10) Pub. No.: US 2025/0393366 A1
(43) Pub. Date: Dec. 25, 2025

(54) DISPLAY DEVICE AND WEARABLE ELECTRONIC DEVICE INCLUDING THE SAME

(71) Applicant: Samsung Display Co., Ltd., Yongin-si (KR)

(72) Inventors: Geun Ho LEE, Yongin-si (KR); Jang Mi KANG, Yongin-si (KR); Min Kyu WOO, Yongin-si (KR); Byung Chang YU, Yongin-si (KR)

(21) Appl. No.: 19/228,630

(22) Filed: Jun. 4, 2025

(30) Foreign Application Priority Data
Jun. 20, 2024 (KR) 10-2024-0080385
Sep. 11, 2024 (KR) 10-2024-0124220

(51) Int. Cl. H10H 29/49; H10H 29/80; H10H 29/852

(52) U.S. Cl. CPC H10H 29/49; H10H 29/842; H10H 29/852

(57) ABSTRACT

A display device includes: a substrate on which a display area and a non-display area are defined; a pixel circuit layer on the substrate; a plurality of light emitting elements on the pixel circuit layer in the display area; a first conductive pattern on the pixel circuit layer in the display area; dam structures on the substrate in the non-display area; a second conductive pattern disposed between two adjacent dam structures of the dam structures in the non-display area; and an insulating layer disposed on the light emitting elements, the first conductive pattern, the dam structures, and the second conductive pattern. The first conductive pattern and the second conductive pattern may be disposed in substantially the same layer and include the same material.

### CROSS-REFERENCE TO RELATED PATENT APPLICATION

This application claims priority to and the benefit of Korean Patent Application Number 10-2024-0080385, filed on Jun. 20, 2024, and Korean Patent Application Number 10-2024-0124220, filed on Sep. 11, 2024, in the Korean Intellectual Property Office, the entire disclosure of each of which is incorporated herein by reference.

### BACKGROUND

### 1. Field

One or more aspects of embodiments of the present disclosure relate to a display device and a wearable electronic device including the same.

### 2. Description of the Related Art

In recent years, with the growing interest in information displays, there has been consistent research and development consistently focused and conducted on display devices.

### SUMMARY

Display devices, such as wearable device, televisions, monitors, smartphones, and/or tablets, which provide images to users, include display panels for image presentation. Various display panels are being developed, including liquid crystal display panels, organic light-emitting display panels, electrowetting display panels, and/or electrophoretic display panels.

To improve reliability of the display panels, research has been conducted on methods for patterning light-emitting elements.

One or more aspects of embodiments of the present disclosure are directed toward a display device with improved reliability and a wearable electronic device including the same. However, aspects of the present disclosure are not restricted to those set forth herein.

The preceding and other aspects of the present disclosure will become more apparent to one of ordinary skill in the art to which the present disclosure pertains by referencing the detailed description of the present disclosure.

A display device according to one or more embodiments includes: a substrate on which a display area and a non-display area are defined; a pixel circuit layer arranged on the substrate; a plurality of light emitting elements arranged on the pixel circuit layer in the display area and emitting (e.g., configured to emit) light; a first conductive pattern arranged on the pixel circuit layer in the display area and arranged to be spaced and/or apart (e.g., spaced apart or separated) from each of the plurality of light emitting elements; dam structures arranged on the substrate in the non-display area; a second conductive pattern arranged between two adjacent dam structures of the dam structures in the non-display area; and an insulating layer arranged on the plurality of light emitting elements, the first conductive pattern, the dam structures, and the second conductive pattern. The first conductive pattern and the second conductive pattern may be arranged in the (e.g., a) same layer and include the (e.g., a) same material. The pixel circuit layer and each of the dam structures may be provided as multilayers including at least one (e.g., or more) conductive layers and at least one (e.g., or more) insulating layers. At least one layer of the pixel circuit layer and at least one layer of each of the dam structures may be provided in the (e.g., a) same layer.

The first conductive pattern may be provided in the form of filling a space surrounded by two adjacent light emitting elements among the light emitting elements and the insulating layer between the two light emitting elements. The second conductive pattern may be provided in the form of filling a space surrounded by the two adjacent dam structures and the insulating layer between the two dam structures.

The display device may further include a cathode electrode that is arranged on the insulating layer and electrically connected to the first conductive pattern, the second conductive pattern, and the light emitting elements.

The cathode electrode may be arranged directly on the first conductive pattern and the second conductive pattern.

The pixel circuit layer may include an inter-layer dielectric layer formed on the substrate; a first conductive layer arranged on the inter-layer dielectric layer; a first passivation layer formed on the first conductive layer and the inter-layer dielectric layer; a second conductive layer arranged on the first passivation layer; and a second passivation layer arranged on the second conductive layer and the first passivation layer. Each of the dam structures may include a metal layer, a first insulating pattern, a dummy pattern, and a second insulating pattern that are sequentially laminated on the substrate.

The metal layer may be formed of the first conductive layer, the first insulating pattern may be formed of the first passivation layer, the dummy pattern may be formed of the second conductive layer, and the second insulating pattern may be formed of the second passivation layer. The metal layer and the dummy pattern may be electrically connected.

The display device may further include a power line provided in the non-display area and supplying a low potential voltage to the cathode electrode; and a bridge pattern arranged between the power line and the cathode electrode and electrically connecting the power line and the cathode electrode. The power line may be provided in the (e.g., a) same layer as the metal layer and include the (e.g., a) same material as the metal layer. The bridge pattern may be provided in the (e.g., a) same layer as the dummy pattern and include the (e.g., a) same material as the dummy pattern.

At least one of the dam structures may be configured by including the power line, the first insulating pattern arranged on the power line, the bridge pattern arranged on the first insulating pattern, and a second insulating pattern arranged on the bridge pattern.

The insulating layer may include a first opening exposing a portion of each of the light emitting elements and a second opening exposing a portion of the bridge pattern. The cathode electrode may be electrically connected to the light emitting elements through the first opening and to the bridge pattern through the second opening.

The insulating layer may further include a third opening exposing a portion of the dummy pattern of each of the dam structures. The cathode electrode may be electrically connected to the dummy pattern through the third opening.

Each of the dam structures may further include a first layer, a second layer, and a third layer that are arranged between the substrate and the metal layer. The first and third layers may be inorganic insulating patterns, and the second layer may be conductive patterns.

The display device may further include an anode electrode that is arranged on the pixel circuit layer in the display area. Each of the light emitting elements may include a first end and a second end in a longitudinal direction. The first end may be electrically connected to the anode electrode, and the second end may be electrically connected to the cathode electrode.

Each of the light emitting elements may include a first semiconductor layer positioned at the first end and electrically connected to the anode electrode; a second semiconductor layer positioned at the second end and electrically connected to the cathode electrode; and an active layer arranged between the first semiconductor layer and the second semiconductor layer. The first semiconductor layer may be a p-type (kind) semiconductor layer doped with a p-type (kind) dopant, and the second semiconductor layer may be an n-type (kind) semiconductor layer doped with an n-type (kind) dopant.

The first conductive pattern and the second conductive pattern may include copper.

A display device according to one or more embodiments may include a substrate on which a display area and a non-display area are defined; a pixel circuit layer arranged on the substrate; a plurality of light emitting elements arranged on the pixel circuit layer in the display area and emitting (e.g., configured to emit) light; dam structures arranged on the substrate in the non-display area; a dummy pattern arranged between two adjacent dam structures of the dam structures in the non-display area; and a cathode electrode arranged on the light emitting elements, the dam structures, and the dummy pattern. Each of the dam structures may be provided in the (e.g., a) same layer as at least one insulating layer of the pixel circuit layer and include the (e.g., a) same material as the at least one insulating layer. The dummy pattern may be provided in the (e.g., a) same layer as at least one conductive layer of the pixel circuit layer and include the (e.g., a) same material as the at least one conductive layer.

The dummy pattern may be provided in the form of filling a space surrounded by the two adjacent dam structures between the two dam structures.

The pixel circuit layer may include an inter-layer dielectric layer formed on the substrate; a first conductive layer arranged on the inter-layer dielectric layer; a first passivation layer formed on the first conductive layer and the inter-layer dielectric layer; and a second conductive layer arranged on the first passivation layer. Each of the dam structures may be an insulating pattern formed of the first passivation layer. The dummy pattern may be formed of the second conductive layer.

The display device may further include a power line provided in the non-display area and supplying a low potential voltage to the cathode electrode. The cathode electrode may be arranged directly on the dummy pattern and electrically connected to the dummy pattern.

The display device may further include a first connection line arranged in the non-display area and extending in a first direction; and a second connection line arranged in the non-display area and extending in a second direction intersecting the first direction. The dummy pattern may be electrically connected to another dummy pattern adjacent in the first direction through the first connection line. The dummy pattern may be electrically connected to another dummy pattern adjacent in the second direction through the second connection line. The dummy pattern, the first connection line, and the second connection line may be connected to each other to have a mesh structure.

A wearable electronic device according to one or more embodiments may include: a display panel; and a lens arranged on the display panel. The display panel may include a substrate on which a display area and a non-display area are defined; a pixel circuit layer arranged on the substrate; a plurality of light emitting elements arranged on the pixel circuit layer in the display area and emitting (e.g., configured to emit) light; a first conductive pattern arranged on the pixel circuit layer in the display area and arranged to be spaced and/or apart (e.g., spaced apart or separated) from each of the plurality of light emitting elements; dam structures arranged on the substrate in the non-display area; a second conductive pattern arranged between two adjacent dam structures of the dam structures in the non-display area; and an insulating layer arranged on the plurality of light emitting elements, the first conductive pattern, the dam structures, and the second conductive pattern.

The first conductive pattern and the second conductive pattern may be arranged in the (e.g., a) same layer and include the (e.g., a) same material. The pixel circuit layer and each of the dam structures may be provided as multilayers including at least one (e.g., or more) conductive layers and at least one (e.g., or more) insulating layers. At least one layer of the pixel circuit layers and at least one layer of each of the dam structures may be provided in the same layer.

In a display device and a wearable electronic device according to one or more embodiments, while a conductive pattern is arranged to secure a pattern density throughout a display area and a non-display area, by forming a dam structure that defines a position at which the conductive pattern is to be formed in the non-display area with configurations (e.g., an insulating layer and a conductive layer) arranged in a pixel circuit layer, a separate process for forming the structure may not be provided.

In some embodiments, the display device and the wearable electronic device according to one or more embodiments may electrically connect the structure with a cathode electrode, thereby improving reliability by reducing the resistance of the cathode electrode and improving the voltage drop.

Effects according to one or more embodiments are not limited to those exemplified herein, and more diverse effects are included in the present specification.

### BRIEF DESCRIPTION OF THE DRAWINGS

The accompanying drawings are included to provide a further understanding of the preceding and other advantages of the present disclosure and are incorporated in and constitute a part of this specification. The drawings illustrate example embodiments that will become readily apparent with reference to the following detailed description when considered in conjunction with the accompanying drawings wherein:

FIG. 1 is a schematic block diagram illustrating one or more embodiments of a display device.

FIG. 2 is a schematic block diagram illustrating one or more embodiments of one of the sub-pixels of FIG. 1.

FIG. 3 is a schematic plan view illustrating one or more embodiments of a display device of FIG. 1.

FIG. 4 is a schematic cross-sectional diagram illustrating one or more embodiments of a display panel of FIG. 3.

FIG. 5 is a schematic cross-sectional diagram illustrating one or more embodiments of a display panel of FIG. 3.

FIG. 6 is a schematic plan view illustrating one or more embodiments of one of pixels of FIG. 3.

FIG. 7 is a schematic cross-sectional diagram taken along the line I-I′ of FIG. 6.

FIG. 8A and FIG. 8B are schematic cross-sectional diagrams corresponding to line I-I′ of FIG. 6, illustrating modified embodiments of FIG. 7 with respect to configurations on a display element layer.

FIG. 9 is a schematic plan view illustrating a display device according to one or more embodiments.

FIG. 10 is an enlarged schematic diagram illustrating an EA area of FIG. 9.

FIG. 11 is a schematic cross-sectional diagram taken along the line II-II′ of FIG. 10.

FIG. 12-FIG. 14 are schematic cross-sectional diagrams corresponding to line II-II′ of FIG. 10, illustrating a portion of a non-display area of a display device according to one or more embodiments.

FIG. 15-FIG. 25 are schematic cross-sectional diagrams illustrating a method of manufacturing a display device according to one or more embodiments.

FIG. 26 is an enlarged schematic diagram corresponding to an EA area of FIG. 9, illustrating a portion of a non-display area of a display device according to one or more embodiments.

FIG. 27 is a schematic cross-sectional diagram taken along the line III-III′ of FIG. 26.

FIG. 28 is a schematic block diagram illustrating one or more embodiments of a display system.

FIG. 29-FIG. 32 are schematic diagrams illustrating applied embodiments of the display system of FIG. 28.

### DETAILED DESCRIPTION

Hereinafter, embodiments according to the present disclosure will be described in more detail with reference to the accompanying drawings. It should be noted that the following explanation describes only parts necessary to understand the operation of the present disclosure, and other parts of the description will not be provided not to obscure the gist of the present disclosure. In some embodiments, the present disclosure is not limited to one or more embodiments described herein, but may be embodied in other forms. However, one or more embodiments described herein is provided to explain in such detail as to facilitate implementation of the technical idea of the present disclosure to a person skilled in the art to which the present disclosure pertains.

Throughout the specification, if a part is “connected” to another part, this includes not only a case where they are “directly connected”, but also a case where they are “indirectly connected” with another element interposed therebetween. Terminology used herein is intended to describe specific embodiments and is not intended to limit the present disclosure.

Throughout the specification, if a part “comprising,” “comprise,” “comprises,” “includes,” “include,” “including,” “has,” “have,” and/or “having,” a component, it refers to that it may further include other component rather than excluding other components unless the context indicates otherwise. Additionally, the terms “comprise(s)/comprising,” “include(s)/including,” “have/has/having” or similar terms include or support the terms “consisting of” and “consisting essentially of,” indicating the presence of stated features, integers, steps, operations, elements, and/or components, without or essentially without the presence of other features, integers, steps, operations, elements, components, and/or groups thereof. In this context, “consisting essentially of” indicates that any additional components will not materially affect the chemical, physical, optical or electrical properties of the semiconductor film.

Expressions such as “at least one of,” “one of,” “selected from,” and “selected from among,” when preceding a list of elements, modify the entire list of elements and do not modify the individual elements of the list. For example, throughout the disclosure, the expressions “at least any one of X, Y, and Z” and “at least any one selected from among a group of X, Y, and Z” may be interpreted as one X, one Y, one Z, and/or a (e.g., any suitable) combination of two or more of X, Y, and Z (e.g., XYZ, XY, YZ, XZ). Herein, “and/or” includes all combinations of one or more of corresponding configurations.

Herein, terms such as first and second may be used to describe one or more suitable components, but these components are not limited to these terms. These terms are used to distinguish one component from another component. Accordingly, a first component may be referred to as a second component without departing from the present disclosure. As used herein, the singular forms, “a”, “an” and “the” are intended to include the plural forms as well, unless the context clearly indicates otherwise.

Spatially relative terms such as “below” and “above” may be used for illustrative purposes, thereby describing the relationship of one element or feature to another element(s) or feature(s) as shown in the drawings. The spatially relative term is intended to include different orientations of device in use, operation, and/or manufacture, in addition to the orientation depicted in the drawing. For example, if a device shown in the drawing is turned over, elements depicted as being positioned “below” other elements or features would be positioned “above” the other elements or features. Hence, the term “below” may include both (e.g., simultaneously) upward and downward directions in one or more embodiments. Besides, the device may be oriented in other directions (e.g., rotated 90 degrees or in a different direction), and thus the spatially relative terms used herein are interpreted accordingly. Like numerals refer to like elements throughout, and duplicative descriptions thereof may not be provided. In the drawings, the thickness, ratio, and dimension of components are exaggerated for effective description of the technical content.

Various embodiments are described with reference to drawings illustrating ideal embodiments. Accordingly, it is to be expected, for example, that shapes may change depending on tolerances and/or manufacturing techniques. Thus, one or more embodiments disclosed herein may not be construed as being limited to the specific shapes depicted, but should be construed as including variations of the shapes resulting from, for example, manufacturing. As such, the shapes shown in the drawings may not show actual shapes of areas of the device, and the present embodiments are not limited thereto.

Unless otherwise defined, all terms including chemical, technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

The term “may” will be understood to refer to “one or more embodiments of the present disclosure,” some of which include the described element and some of which exclude that element and/or include an alternate element. Similarly, alternative language such as “or” refers to “one or more embodiments of the present disclosure,” each including a corresponding listed item.

Hereinafter, embodiments of the present disclosure will be described with reference to accompanying drawings in which one or more embodiments of present disclosure are shown. An aspect and a characteristic of the disclosure, and a method of accomplishing these will be apparent referring to one or more embodiments described with reference to the drawings. In this specification, phrases such as “on a plane,” “plan view,” and/or the like indicate viewing a target portion from the top, and the phrase “on a cross-section” indicates viewing a cross-section formed by vertically cutting a target portion from the side.

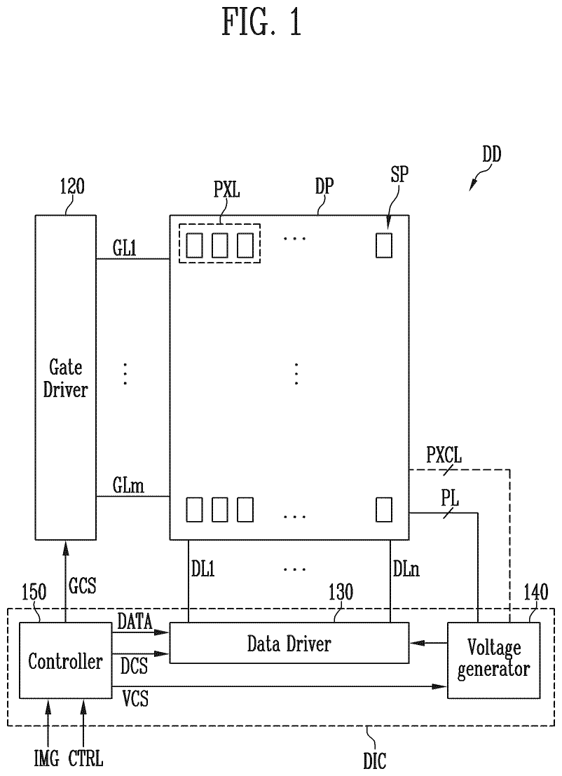

FIG. 1 is a schematic block diagram illustrating one or more embodiments of a display device DD.

Referring to FIG. 1, the display device DD may include a display panel DP, a gate driver 120, a data driver 130, a voltage generator 140, and a controller 150.

The display panel DP may include sub-pixels SP. The sub-pixels SP may be connected to the gate driver 120 through first to m-th gate lines GL1 to GLm. The sub-pixels SP may be connected to the data driver 130 through first to n-th data lines DL1 to DLn.

The sub-pixels SP may generate light of two or more colors. For example, each of the sub-pixels SP may generate light such as red, green, blue, cyan, magenta, and yellow.

Two or more of the sub-pixels SP may form a single pixel PXL. For example, the pixel PXL may include three sub-pixels SP, as shown in FIG. 1. As such, the pixel PXL may be to emit light of one or more suitable colors and one or more suitable brightness depending on the combination of light emitted from the sub-pixels SP included therein.

The gate driver 120 may be connected to sub-pixels SP arranged in a row direction through the first to m-th gate lines GL1 to GLm. The gate driver 120 may output gate signals to the first to m-th gate lines GL1 to GLm in response to a gate control signal GCS. In one or more embodiments, the gate control signal GCS may include a start signal indicating the start of each frame and a horizontal synchronization signal.

The gate driver 120 may be arranged on one side of the display panel DP, but the present disclosure is not limited thereto. For example, the gate driver 120 may be divided into two or more physically and/or logically distinct drivers, and such drivers may be arranged on one side of the display panel DP and the other side of the display panel DP that is opposed to the one side. Thus, the gate driver 120 may be arranged around the display panel DP in one or more suitable forms according to one or more embodiments.

The data driver 130 is connected to the sub-pixels SP arranged in a column direction through the first to n-th data lines DL1 to DLn. The data driver 130 receives image data DATA and data control signals DCS from the controller 150. The data driver 130 operates in response to the data control signal DCS. In one or more embodiments, the data control signal DCS may include a source start signal, a source shift clock signal, and a source output enabling signal.

The data driver 130 may receive voltages from the voltage generator 140. The data driver 130 may, using the received voltages, apply data signals having gray scale voltages corresponding to the image data DATA to the first to n-th data lines DL1 to DLn. When the gate signal is applied to each of the first to m-th gate lines GL1 to GLm, the data signals corresponding to the image data DATA may be applied to the data lines DL1 to DLn. Thereby, the sub-pixels SP may generate light corresponding to the data signals, and the display panel DP may display the image.

In one or more embodiments, the gate driver 120 and the data driver 130 may include complementary metal-oxide semiconductor (CMOS) circuit elements.

The voltage generator 140 may operate in response to a voltage control signal VCS from the controller 150. The voltage generator 140 is configured to generate a plurality of voltages and provide the generated voltages to components of the display devices DD such as the gate driver 120, the data driver 130, and the controller 150. The voltage generator 140 may generate a plurality of voltages by receiving input voltages from the outside of the display device DD and regulating the received voltages.

The voltage generator 140 may generate a first power voltage and a second power voltage. The generated first and second power voltages may be provided to the sub-pixels SP through power lines PL. In one or more embodiments, at least one of the first and second power voltages may be provided from the outside of the display device DD.

In some embodiments, the voltage generator 140 may provide one or more suitable voltages and/or signals. For example, the voltage generator 140 may provide one or more initialization voltages applied to the sub-pixels SP. For example, upon the sensing operation to sense the electrical properties of transistors and/or light emitting elements of the sub-pixels SP, a set or predetermined reference voltage may be applied to the first to n-th data lines DL1 to DLn, and the voltage generator 140 may generate the reference voltage to transmit to the data driver 130. For example, upon the display operation to display an image on the display panel DP, common pixel control signals may be applied to the sub-pixels SP, and the voltage generator 140 may generate the pixel control signals. In one or more embodiments, the voltage generator 140 may provide the pixel control signals to the sub-pixels SP through pixel control lines PXCL. In FIG. 1, the pixel control lines PXCL are shown to be connected between the voltage generator 140 and the display panel DP, but embodiments are not limited thereto. For example, the pixel control lines PXCL may be connected between the gate driver 120 and the display panel DP. In this case, the pixel control signals may be transmitted from the voltage generator 140 to the pixel control lines PXCL through the gate driver 120.

The controller 150 controls all operations of the display device DD. The controller 150 receives, from the outside, input image data IMG and a control signal CTRL corresponding thereto. The controller 150 may respond to the control signal CTRL and provide the gate control signal GCS, the data control signal DCS, and the voltage control signal VCS.

The controller 150 may output the image data DATA by converting the input image data IMG to fit the display device DD or the display panel DP. In one or more embodiments, the controller 150 may output the image data DATA by aligning the input image data IMG to fit the sub-pixels SP in a row unit.

Two or more components of the data driver 130, the voltage generator 140, and the controller 150 may be mounted in a single integrated circuit. As shown in FIG. 1, the data driver 130, the voltage generator 140, and the controller 150 may be included in the driver integrated circuit DIC. In this case, the data driver 130, the voltage generator 140, and the controller 150 may be functionally distinct components within a single driver integrated circuit DIC. In one or more embodiments, at least one of the data driver 130, the voltage generator 140, and the controller 150 may be provided as a distinct component from the driver integrated circuit DIC.

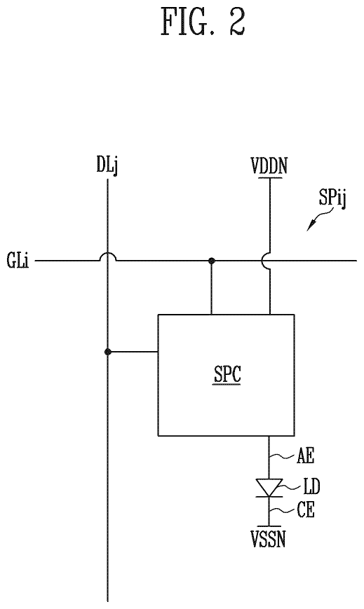

FIG. 2 is a schematic block diagram illustrating one or more embodiments of one of sub-pixels SP of FIG. 1. In FIG. 2, the sub-pixel SPij arranged in an i-th row (where i is greater than or equal to 1 and less than or equal to m) and a j-th column (where j is greater than or equal to 1 and less than or equal to n) of the sub-pixels SP of FIG. 1 is illustratively shown.

Referring to FIG. 2, the sub-pixel SPij may include a sub-pixel circuit SPC and a light emitting element LD.

The light emitting element LD may be connected between a first power voltage node VDDN and a second power voltage node VSSN. The first power voltage node VDDN may be connected to one of the power lines PL of FIG. 1 and receive the first power voltage. The second power voltage node VSSN may be connected to the other one of the power lines PL of FIG. 1 and receive the second power voltage. The first power voltage may have a higher voltage level than the second power voltage.

The light emitting element LD may be connected between an anode electrode AE and a cathode electrode CE. The anode electrode AE may be connected to the first power voltage node VDDN through the sub-pixel circuit SPC. For example, the anode electrode AE may be connected to the first power voltage node VDDN through one or more transistors included in the sub-pixel circuit SPC. The light emitting element LD may be configured to emit light according to the current flowing from the anode electrode AE to the cathode electrode CE.

The sub-pixel circuit SPC may be connected to the i-th gate line GLi of the first to m-th gate lines GL1 to GLm of FIG. 1 and the j-th data line DLj of the first to n-th data lines DL1 to DLn of FIG. 1. In response to the gate signal received through the i-th gate line GLi, the sub-pixel circuit SPC controls the light emitting element LD to emit light according to the data signal received through the j-th data line DLj. In one or more embodiments, the sub-pixel circuit SPC may be further connected to the pixel control lines PXCL of FIG. 1. In this case, the sub-pixel circuit SPC may control the light emitting element LD by responding more to the pixel control signals received through the pixel control lines PXCL.

For these operations, the sub-pixel circuit SPC may include circuit elements such as transistors and one or more capacitors.

The transistors in the sub-pixel circuit SPC may include P-type (kind) transistors and/or N-type (kind) transistors. In one or more embodiments, the transistors in the sub-pixel circuit SPC may include a metal oxide silicon field effect transistor (MOSFET). In one or more embodiments, transistors in the sub-pixel circuit SPC may include amorphous silicon semiconductors, monocrystalline silicon, polycrystalline silicon semiconductors, and/or oxide semiconductors.

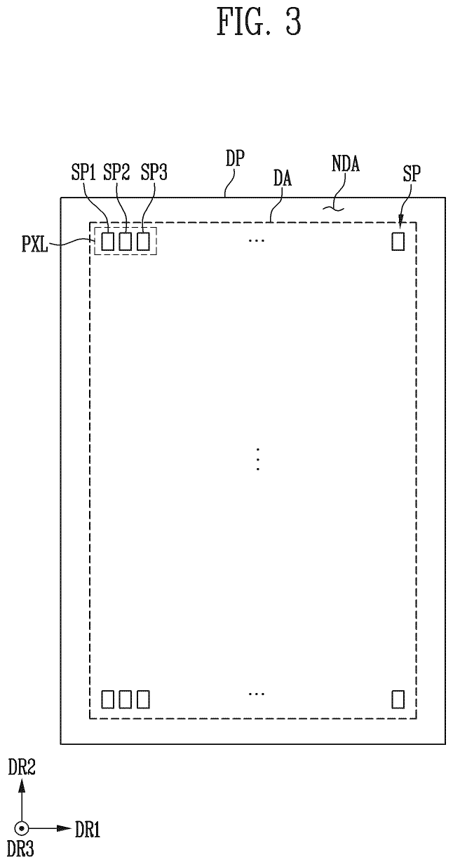

FIG. 3 is a schematic plan view illustrating one or more embodiments of a display device DD of FIG. 1. In FIG. 3, for convenience, briefly shown is a structure of the display device DD centered on the display area DA where the image is displayed, for example, the display panel DP provided in the display device DD.

Referring to FIG. 3, the display device DD (or the display panel DP) may include a display area DA and a non-display area NDA. The display panel DP may display images through the display area DA. The non-display area NDA may be arranged around the display area DA.

The display panel DP may include sub-pixels SP in the display area DA. The sub-pixels SP may be arranged along a second direction DR2 intersecting a first direction DR1. For example, the sub-pixels SP may be arranged in a matrix form along the first direction DR1 and the second direction DR2. As another example, the sub-pixels SP may be arranged in a zigzag form along the first direction DR1 and the second direction DR2. The arrangement of the sub-pixels SP may vary according to one or more embodiments. The first direction DR1 may be a row direction, and the second direction DR2 may be a column direction, but the embodiments of the present disclosure are not limited thereto.

Two or more sub-pixels of a plurality of sub-pixels SP may configure a single pixel PXL. In FIG. 3, the pixel PXL is shown to include three sub-pixels SP1 to SP3, but one or more embodiments herein are not limited thereto. For example, the pixel PXL may include two sub-pixels. As an example, the pixel PXL may include the first sub-pixel SP1, the second sub-pixel SP2, and the third sub-pixel SP3.

Each of the first to third sub-pixels SP1 to SP3 may generate light of one or more suitable colors, such as red, green, blue, cyan, magenta, and/or yellow. Hereinafter, for a clear and concise explanation, it is assumed that the first sub-pixel SP1 is configured to generate red light, the second sub-pixel SP2 is configured to generate green light, and the third sub-pixel SP3 is configured to generate blue light.

Each of the first to third sub-pixels SP1 to SP3 may include at least one light emitting element configured to generate light. In one or more embodiments, the light emitting elements of the first to third sub-pixels SP1 to SP3 may generate light of different colors. For example, the light emitting elements of the first to third sub-pixels SP1 to SP3 may generate red, green, and blue light, respectively. In one or more embodiments, the light emitting elements of the first to third sub-pixels SP1 to SP3 may generate light of the same color.

Used as the display panel DP may be a display panel capable of self-emitting light, such as a light emitting diode (LED) display panel that uses a micro or nanoscale light emitting diode as a light emitting element, or an organic light emitting display (OLED) panel that uses an organic light emitting diode as a light emitting element.

In the non-display area NDA, a component may be arranged to control the sub-pixels SP. Wirings connected to the sub-pixels SP, e.g., the first to m-th gate lines GL1 to GLm, the first to n-th data lines DL1 to DLn, the power lines PL, and the pixel control lines PXCL of FIG. 1 may be arranged in the non-display area NDA.

At least one of the gate driver 120, the data driver 130, the voltage generator 140, and the controller 150 of FIG. 1 may be arranged in the non-display area NDA of the display panel DP. In one or more embodiments, the gate driver 120 may be arranged in the non-display area NDA. In such a case, the data driver 130, the voltage generator 140, and the controller 150 may be implemented as the driver integrated circuit DIC of FIG. 1 that is distinct from the display panel DP, and the driver integrated circuit DIC may be connected to the wirings arranged in the non-display area NDA. In one or more embodiments, the gate driver 120 may be implemented as a single integrated circuit that is distinct from the display panel DP along with the data driver 130, the voltage generator 140, and the controller 150.

In one or more embodiments, the display area DA may have one or more suitable shapes. The display area DA may have a closed-loop shape including straight and/or curved sides. For example, the display area DA may have shapes such as polygons, circles, semicircles, and ellipses.

In one or more embodiments, the display panel DP may have a flat display surface. In one or more embodiments, the display panel DP may have at least a partially rounded display surface. In one or more embodiments, the display panel DP may be bendable, foldable, or rollable. In these cases, the display panel DP and/or the substrate of the display panel DP may include materials having flexibility.

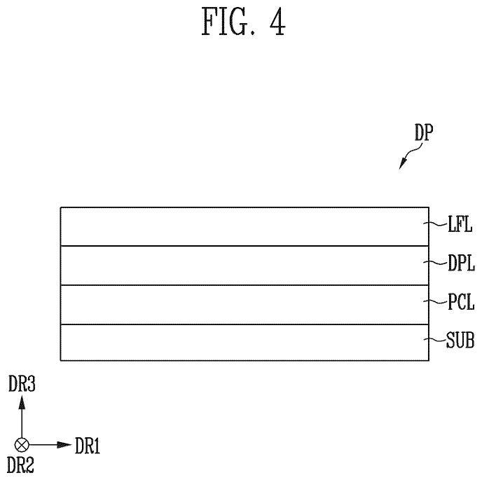

FIG. 4 is a schematic cross-sectional diagram illustrating one or more embodiments of the display panel DP of FIG. 3.

Referring to FIG. 3 and FIG. 4, the display panel DP may include a substrate SUB as well as a pixel circuit layer PCL, and a display element layer DPL that are sequentially laminated in a third direction DR3 intersecting with the first and second directions DR1 and DR2 on the substrate SUB.

The substrate SUB may include (e.g., be made up of) insulating materials such as glass and resin. For example, the substrate SUB may include a glass substrate. As another example, the substrate SUB may include a polyimide (PI) substrate. As another example, the substrate SUB may include silicon wafer substrates formed using semiconductor processes.

In one or more embodiments, the substrate SUB may include or be formed of a flexible material that allows bending or folding and have a single layer structure or a multilayer structure. For example, flexible materials may include at least one of (e.g., selected from among) polystyrene, polyvinyl alcohol, polymethyl methacrylate, polyethersulfone, polyacrylate, polyetherimide, polyethylene naphthalate, polyethylene terephthalate, polyphenylene sulfide, polyarylate, polyimide, polycarbonate, triacetate cellulose, and cellulose acetate propionate. However, embodiments are not limited thereto.

The pixel circuit layer PCL may be arranged on the substrate SUB. The pixel circuit layer PCL may include the insulating layers as well as semiconductor patterns and conductive patterns that are arranged between the insulating layers. The conductive patterns of the pixel circuit layer PCL may function as circuit elements and wirings.

The circuit elements of the pixel circuit layer PCL may include the sub-pixel circuit (see “SPC” in FIG. 3) for each of the sub-pixels SP of FIG. 3. For example, circuit elements in the pixel circuit layer PCL may be provided as transistors and one or more capacitors in the sub-pixel circuit SPC.

The wirings of the pixel circuit layer PCL may include wirings connected to the sub-pixels SP. The wirings of the pixel circuit layer PCL may include one or more suitable signal lines and/or voltage lines desired or required to drive the display element layer DPL.

The display element layer DPL may be arranged on the pixel circuit layer PCL. The display element layer DPL may include light emitting elements LD of the sub-pixels SP.

According to one or more embodiments, a light functional layer LFL may be arranged on the display element layer DPL. The light functional layer LFL may include light conversion patterns having color conversion particles and/or scattering particles. For example, color conversion particles may include quantum dots. The quantum dots may change the wavelength (or color) of light emitted from the display element layer DPL. The light functional layer LFL may further include light scattering patterns having the scattering particles. In one or more embodiments, the light conversion patterns and the light scattering patterns may not be provided.

The light functional layer LFL may further include a color filter layer that includes color filters. The color filter may selectively transmit light of a specific wavelength (or a specific color). In one or more embodiments, the color filter layer may not be provided.

A window may be provided on the light functional layer LFL to protect an exposed surface (or an upper surface) of the display panel DP. The window may protect the display panel DP from external shocks. The window may be bonded to the light functional layer LFL through an optical transparent adhesive (or cohesive) member. The window may have a multilayer structure selected from among a glass substrate, a plastic film, or a plastic substrate. These multilayer structures may be formed through a substantially continuous process or an adhesive process using an adhesive layer. The entire (e.g., all), (or only a part of the) window may have flexibility.

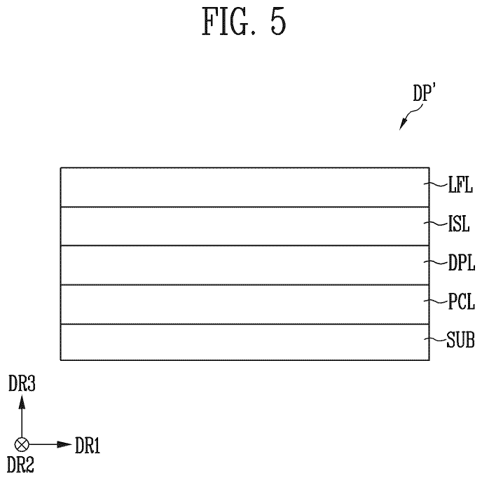

FIG. 5 is a schematic cross-sectional diagram illustrating one or more embodiments of a display panel DP of FIG. 3.

Referring to FIG. 5, a display panel DP′ may include the substrate SUB, the pixel circuit layer PCL, the display element layer DPL, an input sensing layer ISL, and a light functional layer LFL. The substrate SUB, the pixel circuit layer PCL, the display element layer DPL, and the light functional layer LFL may be configured to be substantially similar to the substrate SUB, the pixel circuit layer PCL, the display element layer DPL, and the light functional layer LFL described in reference to FIG. 4. Hereinafter, duplicate explanations are not provided.

The input sensing layer ISL may sense user input for the upper surface (or a display surface) of the display panel DP′. The input sensing layer ISL may include configurations suitable for sensing external objects such as the user's hand and pen. For example, the input sensing layer ISL may include touch electrodes.

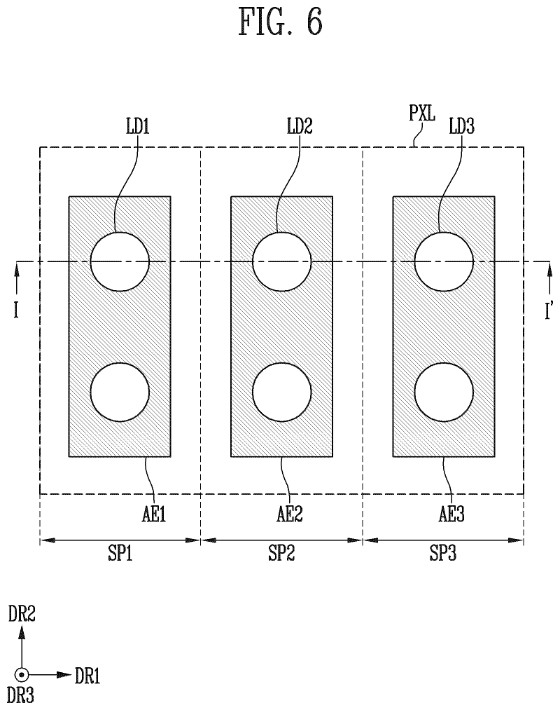

FIG. 6 is a schematic plan view illustrating one or more embodiments of pixels PXL of FIG. 3.

Referring to FIG. 3 and FIG. 6, the pixel PXL may include the first sub-pixel SP1, the second sub-pixel SP2, and the third sub-pixel SP3. The first to third sub-pixels SP1 to SP3 may be arranged in the first direction DR1. However, the arrangement of the pixels PXL is not limited thereto and may vary according to one or more embodiments. For example, the first to third sub-pixels SP1 to SP3 may be arranged in a zigzag.

The anode electrode may be arranged in each of the first to third sub-pixels SP1 to SP3. For example, a first anode electrode AE1 may be arranged in the first sub-pixel SP1, a second anode electrode AE2 may be arranged in the second sub-pixel SP2, and a third anode electrode AE3 may be arranged in the third sub-pixel SP3. The first anode electrode AE1 may be provided as the anode electrode (see “AE” of FIG. 2) included in the sub-pixel circuit (see “SPC” of FIG. 2) of the first sub-pixel SP1. The second anode electrode AE2 may be provided as the anode electrode AE included in the sub-pixel circuit SPC of the second sub-pixel SP2. The third anode electrode AE3 may be provided as the anode electrode AE included in the sub-pixel circuit SPC of the third sub-pixel SP3.

On the first to third anode electrodes AE1 to AE3, at least one light emitting element may be arranged. For example, at least one first light emitting element LD1 may be arranged on the first anode electrode AE1, at least one second light emitting element LD2 may be arranged on the second anode electrode AE2, and at least one third light emitting element LD3 may be arranged on the third anode electrode AE3. The first light emitting elements LD1 may be electrically connected to the first anode electrode AE1. The second light emitting element LD2 may be electrically connected to the second anode electrode AE2. The third light emitting element LD3 may be electrically connected to the third anode electrode AE3. If a plurality of light emitting elements are provided in each sub-pixel, each anode electrode may have a shape that extends in a particular direction, such as the second direction DR2, and the light emitting elements connected to the anode electrode may be arranged in substantially the same direction.

The first light emitting element LD1 may be provided as the light emitting element LD of FIG. 2 included in the first sub-pixel SP1. The second light emitting element LD2 may be provided as the light emitting element LD of FIG. 2 included in the second sub-pixel SP2. The third light emitting element LD3 may be provided as the light emitting element LD of FIG. 2 included in the third sub-pixel SP3. If a plurality of light emitting elements are provided in a single sub-pixel, a plurality of light emitting elements may be provided as the light emitting element LD of FIG. 2 in parallel connection between the anode electrode and the cathode electrode.

The first light emitting element LD1, the second light emitting element LD2, and the third light emitting element LD3 may be formed of, but are not limited to, an inorganic light emitting diode including an inorganic light emitting material. According to one or more embodiments, the first light emitting element LD1, the second light emitting element LD2, and the third light emitting element LD3 may be formed of an organic light emitting diode.

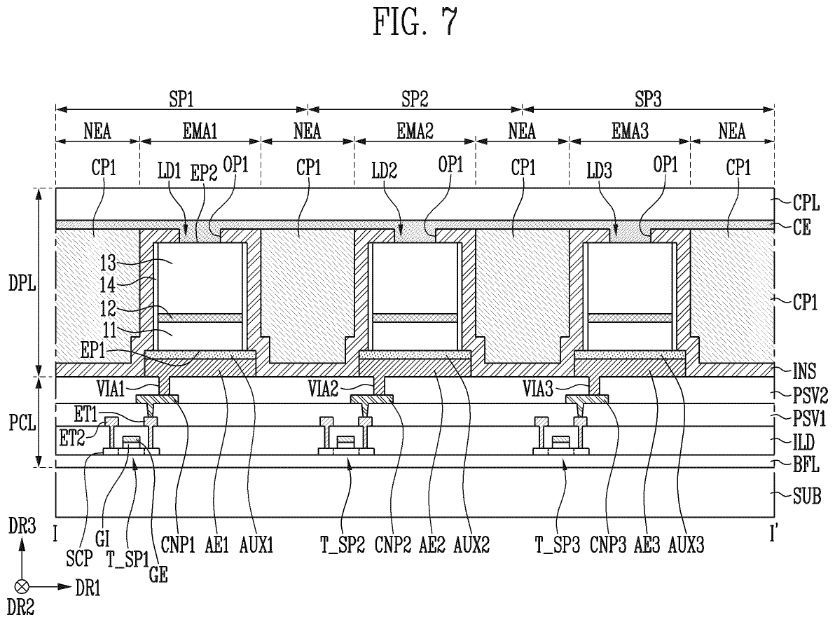

FIG. 7 is a schematic cross-sectional diagram taken along the line I-I′ of FIG. 6.

Referring to FIG. 6 and FIG. 7, the pixel PXL may include the first sub-pixel SP1, the second sub-pixel SP2, and the third sub-pixel SP3 that are arranged along the first direction DR1. Each of the first to third sub-pixels SP1 to SP3 may include the substrate SUB, the pixel circuit layer PCL, and the display element layer DPL. The pixel circuit layer PCL and the display element layer DPL may be arranged on the substrate SUB to overlap each other.

The substrate SUB may include silicon wafer substrates formed using semiconductor processes, but the present disclosure is not limited thereto. According to one or more embodiments, the substrate SUB may include a glass substrate.

The pixel circuit layer PCL may include the insulating layers, the semiconductor patterns, and the conductive pattern that are laminated on the substrate SUB. The insulating layers may include a buffer layer BFL, one or more inter-layer dielectric layers ILD, and one or more passivation layers PSV1 and PSV2. The semiconductor patterns and the conductive patterns may be positioned between the insulating layers. The conductive patterns may include at least one material selected from among (e.g., of) copper, molybdenum, tungsten, aluminum, neodymium, titanium, aluminum, and silver.

As described in reference to FIG. 2, the sub-pixel circuit (see “SPC” of FIG. 2) of each of the first to third sub-pixels SP1 to SP3 may include transistors and one or more capacitors. The semiconductor patterns and the conductive patterns of the pixel circuit layer PCL may function as transistors and capacitors of the sub-pixel circuit SPC. In some embodiments, the conductive patterns of the pixel circuit layer PCL may additionally function as wirings, e.g., the first to m-th gate lines GL1 to GLm, the first to n-th data lines DL1 to DLn, the power lines PL, and the pixel control lines PXCL of FIG. 1.

The pixel circuit layer PCL may include a transistor T_SP1 of the first sub-pixel SP1, a transistor T_SP2 of the second sub-pixel SP2, and a transistor T_SP3 of the third sub-pixel SP3. The transistor T_SP1 of the first sub-pixel SP1 may be one of (e.g., selected from among) the transistors included in the sub-pixel circuit SPC of the first sub-pixel SP1, the transistor T_SP2 of the second sub-pixel SP2 may be one of the transistors included in the sub-pixel circuit SPC of the second sub-pixel SP2, and the transistor T_SP3 of the third sub-pixel SP3 may be one of the transistors included in the sub-pixel circuit SPC of the third sub-pixel SP3. In FIG. 7, for clarity and conciseness in explanation, one of the transistors of each sub-pixel is shown, and descriptions of the remaining circuit elements are not provided.

The buffer layer BFL may be arranged on the substrate SUB. The buffer layer BFL may prevent or reduce the diffusion of impurities in the circuit elements (or drive elements) that make up the sub-pixel circuit SPC, such as transistors. The buffer layer BFL may be an inorganic insulating film including an inorganic substance (or a material). The buffer layer BFL may include at least one selected from among (e.g., of) silicon nitride (SiNₓ), silicon oxide (SiOₓ), silicon oxynitride (SiOₓN_{y}), and aluminum oxide (AlOₓ). The buffer layer BFL may be provided as a single layer, but it may also be provided as a multilayer of at least two layers. The buffer layer BFL may not be provided depending on the substrate material and processing conditions.

According to one or more embodiments, one or more barrier layers may be arranged between the substrate SUB and the buffer layer BFL. Each of the barrier layers may include polyimide, but the present disclosure is not limited thereto.

On the buffer layer BFL, the transistor T_SP1 of the first sub-pixel SP1, the transistor T_SP2 of the second sub-pixel SP2, and the transistor T_SP3 of the third sub-pixel SP3 may be arranged. It may be understood that each of the transistors T_SP1 of the first sub-pixel SP1, the transistors T_SP2 of the second sub-pixel SP2, and the transistors T_SP3 of the third sub-pixels SP3 are transistors that are connected to the anode electrode among the transistors of the corresponding sub-pixel circuit SPC.

The transistor T_SP1 of the first sub-pixel SP1 may include a semiconductor pattern SCP, a gate electrode GE, a first terminal ET1, and a second terminal ET2. The first terminal ET1 may be one selected from among (e.g., of) source electrodes and drain electrodes, and the second terminal ET2 may be the remainder of the source electrode and the drain electrode. For example, the first terminal ET1 may be the source electrode, and the second terminal ET2 may be the drain electrode.

The semiconductor pattern SCP may be arranged on the buffer layer BFL. The semiconductor pattern SCP may include a first contact area coming in contact with the first terminal ET1 and a second contact area coming in contact with the second terminal ET2. The area between the first contact area and the second contact area may be a channel area. The channel area may overlap with the gate electrode GE of the transistor T_SP1 of the first sub-pixel SP1.

The semiconductor pattern SCP may include, but is not limited to, one or more suitable types (kinds) of semiconductors, such as any one selected from among (e.g., of) amorphous silicon semiconductors, monocrystalline silicon semiconductors, polycrystalline silicon semiconductors, low temperature polysilicon semiconductors, and oxide semiconductors.

The inter-layer dielectric layers ILD that are sequentially laminated may be arranged on the semiconductor pattern SCP. The inter-layer dielectric layers ILD may be inorganic insulating layers including inorganic materials. For example, each of the inter-layer dielectric layers ILD may include at least one selected from among (e.g., of) metal oxides, non-metal oxides, non-metal nitrides, and non-metal oxynitrides such as silicon nitride, silicon oxide, silicon oxynitride, and/or aluminum oxide. However, the inter-layer dielectric layers ILD are not limited thereto. For example, any one of the inter-layer dielectric layers ILD may include an organic insulating layer including organic materials.

The inter-layer dielectric layers ILD may electrically separate the conductive patterns and/or the semiconductor patterns arranged between inter-layer dielectric layers ILD from each other. For example, the inter-layer dielectric layers ILD may include a gate insulating layer GI arranged on the semiconductor patterns SCP. The gate insulating layer GI may be arranged between the semiconductor pattern SCP and the gate electrode GE, so that the gate electrode GE is spaced and/or apart (e.g., spaced apart or separated) from the semiconductor pattern SCP. According to one or more embodiments, the gate insulating layer GI may be provided over the whole area on the semiconductor pattern SCP and the buffer layer BFL to cover the semiconductor pattern SCP and the buffer layer BFL. As the number of layers desired or required for the formation of the conductive patterns and/or the semiconductor patterns increases, the number of the inter-layer dielectric layers ILD may increase. The gate electrode GE may be formed of a single conductive layer (e.g., a first gate conductive layer) arranged on the gate insulating layer GI. The gate electrode GE may overlap the channel area of the semiconductor pattern SCP. In one or more embodiments, the gate electrode GE may be provided as a single layer including at least one material selected from among (e.g., of) copper, molybdenum, tungsten, aluminum, neodymium, titanium, aluminum, and silver. In one or more embodiments, the gate electrode GE may be provided as a multilayer including at least one of the low-resistance materials selected from among (e.g., of) molybdenum, titanium, copper, aluminum, and silver.

The first and second terminals ET1 and ET2 may be formed of the other conductive layer (or a second gate conductive layer) arranged on the inter-layer dielectric layer ILD. The first and second terminals ET1 and ET2 may come into contact with the semiconductor pattern SCP through contact holes that penetrate the inter-layer dielectric layers ILD. The first and second terminals ET1 and ET2 may come into contact with the first and second contact areas of the semiconductor pattern SCP, respectively. The first and second terminals ET1 and ET2 may each include at least one material selected from among (e.g., of) copper, molybdenum, tungsten, aluminum, neodymium, titanium, aluminum, and silver.

The first and second terminals ET1 and ET2 are shown as distinct electrodes that are electrically connected to the semiconductor pattern SCP, but embodiments are not limited thereto. In one or more embodiments, the first terminal ET1 may be a first contact area adjacent to one side of the channel area of the semiconductor pattern SCP, and the second terminal ET2 may be a second contact area adjacent to the other side of the channel area. In such a case, the first terminal ET1 may be electrically connected to the light emitting element LD by connection referring to, such as a bridge electrode arranged on at least one of the inter-layer dielectric layers ILD.

In one or more embodiments, the transistor T_SP1 of the first sub-pixel SP1 may be formed of a low temperature poly silicon transistor. However, embodiments are not limited thereto. For example, the transistor T_SP1 of the first sub-pixel SP1 may be formed of an oxide semiconductor transistor. In one or more embodiments, the sub-pixel circuit SPC of the first sub-pixel SP1 may include each different type (kind) of transistors. For example, the transistor T_SP1 of the first sub-pixel SP1 may be formed of a low temperature poly silicon transistor, and the other transistor of the first sub-pixel SP1 may be formed of an oxide semiconductor transistor. In such a case, the oxide semiconductor of the oxide semiconductor transistor may be arranged on any one of the inter-layer dielectric layers ILD other than the insulating layer in which the semiconductor pattern SCP of the transistor T_SP1 of the first sub-pixel SP1 is arranged.

In one or more embodiments, a case where the transistor T_SP1 of the first sub-pixel SP1 is a transistor with a top gate structure is described as an example, but embodiments are not limited thereto. For example, the transistor T_SP1 of the first sub-pixel SP1 may be a transistor with a bottom gate structure. According to one or more embodiments, the transistor T_SP1 of the first sub-pixel SP1 may be configured by including a source area and a drain area arranged to be spaced and/or apart (e.g., spaced apart or separated) from each other within a well formed by an ion injection process in the substrate SUB, and the gate electrode overlapping the channel area between the source area and the drain area and spaced and/or apart (e.g., spaced apart or separated) from the well. In some embodiments, the structure of the transistor T_SP1 may be variously modified.

Each of the transistors T_SP2 of the second sub-pixel SP2 and the transistors T_SP3 of the third sub-pixel SP3 may be configured substantially identical to the transistors T_SP1 of the first sub-pixels SP1.

On the inter-layer dielectric layers ILD, at least some of the one or more suitable wirings of the display panel (see “DP” in FIG. 3) and/or the display device DD may be further arranged.

The first passivation layer PSV1 may be arranged on the inter-layer dielectric layers ILD and the first and second terminals ET1 and ET2. The passivation layer may also be referred to as a protective layer or a via layer. The first passivation layer PSV1 may protect the components arranged on its bottom and provide a flat surface.

A connection pattern may be arranged on the first passivation layer PSV1. For example, a first connection pattern CNP1 may be arranged on the first passivation layer PSV1 of the first sub-pixel SP1, a second connection pattern CNP2 may be arranged on the first passivation layer PSV1 of the second sub-pixel SP2, and a third connection pattern CNP3 may be arranged on the first passivation layer PSV1 of the third sub-pixel SP3. Each of the first to third connection patterns CNP1 to CNP3 may include at least one material selected from among (e.g., of) copper, molybdenum, tungsten, aluminum, neodymium, titanium, aluminum, and silver.

On the first passivation layer PSV1, at least some of the one or more suitable wirings of the display panel DP and/or display device DD may be additionally arranged.

The second passivation layer PSV2 may be arranged on the first to third connection patterns CNP1 to CNP3 and the first passivation layer PSV1. The second passivation layer PSV2 may protect the components arranged on its bottom and provide a flat surface.

Each of the first and second passivation layers PSV1 and PSV2 may include an inorganic insulating layer including inorganic materials and/or an organic insulating layer including organic materials. The inorganic insulating layer, for example, may include at least one of metal oxides, non-metal oxides, non-metal nitrides, and non-metal oxynitrides such as silicon oxide, silicon nitride, silicon oxynitride, or aluminum oxide. The organic insulating layers, for example, may include at least one selected from among (e.g., of) acrylic resins, epoxy-based resins, phenolic resins, polyamide-based resins, polyimide-based resins, unsaturated polyester-based resins, polyphenylene ether-based resins, polyphenylene sulfide-based resins, and benzocyclobutene resins. The first and second passivation layers PSV1 and PSV2 may include the same material as any one of the inter-layer dielectric layers ILD, but embodiments are not limited thereto. Each of the first and second passivation layers PSV1 and PSV2 may be provided as a single layer, but may also be provided as multilayers.

On the second passivation layer PSV2, the display element layer DPL may be arranged. The display element layer DPL may include an anode electrode, an auxiliary electrode, a light emitting element, an element insulating layer INS, a cathode electrode CE, and a capping layer CPL. For example, the display element layer DPL of the first sub-pixel SP1 may include the first anode electrode AE1, a first auxiliary electrode AUX1, the first light emitting element LD1, the element insulating layer INS, the cathode electrode CE, and the capping layer CPL. The display element layer DPL of the second sub-pixel SP2 may include the second anode electrode AE2, a second auxiliary electrode AUX2, the second light emitting element LD2, the element insulating layer INS, the cathode electrode CE, and the capping layer CPL. The display element layer DPL of the third sub-pixel SP3 may include the third anode electrode AE3, a third auxiliary electrode AUX3, the third light emitting element LD3, the element insulating layer INS, the cathode electrode CE, and the capping layer CPL.

The first anode electrode AE1 may be electrically connected to the first connection pattern CNP1 through a first via VIA1 of the second passivation layer PSV2. The first anode electrode AE1 may be electrically connected to the transistor T_SP1 of the first sub-pixel SP1. The second anode electrode AE2 may be electrically connected to the second connection pattern CNP2 through a second via VIA2 of the second passivation layer (PSV2. The second anode electrode AE2 may be electrically connected to the transistor T_SP2 of the second sub-pixel SP2. The third anode electrode AE3 may be electrically connected to the third connection pattern CNP3 through a third via VIA3 of the second passivation layer PSV2. The third anode electrode AE3 may be electrically connected to the transistor T_SP3 of the third sub-pixel SP3.

The first to third anode electrodes AE1 to AE3 may include conductive substances. For example, the first to third anode electrodes AE1 to AE3 may include at least one known conductive materials, such as aluminum, silver, indium tin oxide, indium zinc oxide, zinc oxide, indium gallium zinc oxide, and/or indium tin zinc oxide.

The first auxiliary electrode AUX1 may be arranged on the first anode electrode AE1. The second auxiliary electrode AUX2 may be arranged on the second anode electrode AE2. The third auxiliary electrode AUX3 may be arranged on the third anode electrode AE3. The first to third auxiliary electrodes AUX1 to AUX3 may be formed of conductive substances having a certain reflectivity. For example, the first to third auxiliary electrodes AUX1 to AUX3 may include metals such as silver, magnesium, aluminum, platinum, palladium, gold, nickel, neodymium, iridium, chromium, titanium, and/or alloys thereof. In one or more embodiments, the first to third auxiliary electrodes AUX1 to AUX3 may include at least one of one or more suitable transparent conductive materials, such as indium tin oxide, indium zinc oxide, zinc oxide, indium gallium zinc oxide, and/or indium tin zinc oxide. According to one or more embodiments, the first to third auxiliary electrodes AUX1 to AUX3 may not be provided.

The first light emitting element LD1 may be arranged on the first anode electrode AE1, the second light emitting element LD2 may be arranged on the second anode electrode AE2, and the third light emitting element LD3 may be arranged on the third anode electrode AE3. The first auxiliary electrode AUX1 may be arranged between the first anode electrode AE1 and the first light emitting element LD1, and the second auxiliary electrode AUX2 may be arranged between the second anode electrode AE2 and the second light emitting element LD2, and the third auxiliary electrode AUX3 may be arranged between the third anode electrode AE3 and the third light emitting element LD3. In one or more embodiments, the first auxiliary electrode AUX1 may be a bonding electrode electrically connected to a first semiconductor layer 11 of the first light emitting element LD1, the second auxiliary electrode AUX2 may be a bonding electrode electrically connected to the first semiconductor layer 11 of the second light emitting element LD2, and the third auxiliary electrode AUX3 may be a bonding electrode electrically connected to the first semiconductor layer 11 of the third light emitting element LD3. Each of the first to third auxiliary electrodes AUX1 to AUX3 may include eutectic metal.

The first light emitting element LD1 may include a first end EP1 and a second end EP2 opposite to (e.g., facing) each other in a longitudinal direction. The first end EP1 may come into contact with the first anode electrode AE1 (or the first auxiliary electrode AUX1), and the second end EP2 may come into contact with the cathode electrode CE. The first light emitting element LD1 may include the first semiconductor layer 11, an active layer 12, and a second semiconductor layer 13 that are sequentially laminated along a direction (or the third direction DR3) from the first end EP1 to the second end EP2.

The first semiconductor layer 11 may be connected to the first anode electrode AE1. The first semiconductor layer 11 may include a semiconductor material having a first polarity. In one or more embodiments, the first semiconductor layer 11 may include a p-type (kind) semiconductor layer, in which case the first semiconductor layer 11 may provide a hole to the active layer 12. For example, the first semiconductor layer 11 may include at least one semiconductor material of gallium nitride, aluminum gallium nitride, indium gallium nitride, aluminum nitride, and indium nitride, and may be a p-type (kind) semiconductor layer doped with p-type (kind) dopants such as magnesium, zinc, calcium, strontium, and/or barium.

The second semiconductor layer 13 may be connected to the cathode electrode CE. The second semiconductor layer 13 may include a semiconductor material having a second polarity different from the first polarity. In one or more embodiments, the second semiconductor layer 13 may include an n-type (kind) semiconductor layer, in which case the second semiconductor layer 13 may provide electrons to the active layer 12. For example, the second semiconductor layer 13 may include at least one semiconductor material selected from among gallium nitride, aluminum gallium nitride, indium gallium nitride, aluminum nitride, and indium nitride, and may be an n-type (kind) semiconductor layer doped with n-type (kind) dopants such as selected from among silicon, germanium, and tin.

The active layer 12 may be arranged between the first semiconductor layer 11 and the second semiconductor layer 13. The active layer 12 may provide an area where electrons and holes recombine. As the electrons and the holes recombine in the active layer 12, light having a wavelength corresponding thereto may be generated with transition to a lower energy level. The active layer 12 may be formed in a single- or multi-quantum wells structure. If the active layer 12 is formed as a multi-quantum well structure, units including the barrier layer, a strain reinforcing layer, and a well layer may be repeatedly laminated to form the active layer 12. However, the active layer 12 is not limited thereto.

The first light emitting element LD1 may further include an insulating film 14 around (e.g., surrounding) its outer peripheral surface. The insulating film 14 may include silicon nitride, silicon oxide, and/or silicon oxynitride.

The second and third light emitting elements LD2 and LD3 may be configured as the same as the first light emitting element LD1. Therefore, redundant explanations are not provided.

The first light emitting element LD1 may be to emit light to a first light emitting area EMA1 of the first sub-pixel SP1. The second light emitting element LD2 may be to emit light to a second light emitting area EMA2 of the second sub-pixel SP2. The third light emitting element LD3 may be to emit light to a third light emitting area EMA3 of the third sub-pixel SP3. The first light emitting element LD1 may be a red light emitting diode emitting red light, the second light emitting element LD2 may be a green light emitting diode emitting green light, and the third light emitting element LD3 may be a blue light emitting diode emitting blue light.

The element insulating layer INS may be arranged on the first to third light emitting elements LD1 to LD3 and the second passivation layer PSV2. The element insulating layer INS may be arranged between the pixel circuit layer PCL and the cathode electrode CE. The element insulating layer INS may include an inorganic insulating layer including inorganic materials and/or an organic insulating layer including organic materials. The inorganic insulating layer, for example, may include at least one of metal oxides, non-metal oxides, non-metal nitrides, and non-metal oxynitrides, such as selected from among silicon nitride, silicon oxide, silicon oxynitride, and aluminum oxide. The organic insulating layer may include, for example, at least one selected from among acrylic resins, epoxy-based resins, phenolic resins, polyamide-based resins, polyimide-based resins, unsaturated polyester-based resins, polyphenylene ether-based resins, polyphenylene sulfide-based resins, and benzocyclobutene resins. In one or more embodiments, the element insulating layer INS may be the inorganic insulating layer.

The element insulating layer INS may cover an upper surface and a side surface of the first to third light emitting elements LD1 to LD3 and cover the second passivation layer PSV2 between the first to third light emitting elements LD1 to LD3 that are spaced and/or apart (e.g., spaced apart or separated). The element insulating layer INS may include a first opening OP1 that exposes a portion of each of the first light emitting element LD1, the second light emitting element LD2, and the third light emitting element LD3.

The cathode electrode CE may be arranged on the element insulating layer INS. The cathode electrode CE may be a common electrode that is commonly provided to the first sub-pixel SP1, the second sub-pixel SP2, and the third sub-pixel SP3. The cathode electrode CE may be connected to second semiconductor layers 13 of each of the first to third light emitting elements LD1 to LD3.

The cathode electrode CE may be configured to be substantially transparent or semi-transparent to satisfy a set or predetermined light transmission. For example, the cathode electrode CE may include at least one of one or more suitable transparent conductive materials, such as selected from among indium tin oxide, indium zinc oxide, zinc oxide, indium gallium zinc oxide, and indium tin zinc oxide.

The cathode electrode CE may be electrically connected to the second power voltage node VSSN of FIG. 2. Accordingly, the second power voltage applied to the second power voltage node VSSN may be transmitted to the cathode electrode CE.

The capping layer CPL may be arranged on the cathode electrode CE. The capping layer CPL may be arranged on the cathode electrode CE to cover the entire cathode electrode CE. The capping layer CPL may include at least one of metal oxides, non-metal oxides, non-metal nitrides, and non-metal oxynitrides selected from among silicon nitride, silicon oxide, silicon oxynitride, and aluminum oxide. However, the material of the capping layer CPL is not limited thereto.

In one or more embodiments, the display element layer DPL may further include a first conductive pattern CP1 arranged between adjacent light emitting elements. The first conductive pattern CP1 may be positioned in a non-light emitting area NEA. For example, the first conductive pattern CP1 may be positioned in the non-light emitting area NEA between adjacent sub-pixels in the display area (see “DA” in FIG. 3).

The first conductive pattern CP1 may be arranged on the element insulating layer INS in the form of filling a space between adjacent light emitting elements. For example, between the first light emitting element LD1 and the second light emitting element LD2, the first conductive pattern CP1 may be arranged on the element insulating layer INS between the first light emitting element LD1 and the second light emitting element LD2 to be provided in the form of filling a space surrounded by the element insulating layer INS that covers one side of the first light emitting element LD1, the element insulating layer INS that covers one side of the second light emitting element LD2, and the element insulating layer INS that covers the second passivation layer PSV2. In some embodiments, between the second light emitting element LD2 and the third light emitting element LD3, the first conductive pattern CP1 may be arranged on the element insulating layer INS between the second light emitting element LD2 and the third light emitting element LD3 to be provided in the form of filling a space surrounded by the element insulating layer INS that covers the other side of the second light emitting element LD2, the element insulating layer INS that covers one side of the third light emitting element LD3, and the element insulating layer INS that covers the second passivation layer PSV2.

In one or more embodiments, the first to third light emitting elements LD1 to LD3 in the display area DA may be utilized as a component to define a formation position of the first conductive pattern CP1.

The first conductive pattern CP1 may be formed throughout the non-light emitting area NEA of the display area DA through the chemical mechanical polishing (CMP) process to have a flat upper surface. The upper surface of the first conductive pattern CP1 may be in a colinear position in the first direction DR1 with the upper surface of the element insulating layer INS arranged on the second end EP2 of each of the first to third light emitting elements LD1 to LD3.

The first conductive pattern CP1 may be physically and/or electrically connected to the cathode electrode CE by coming in direct contact with the cathode electrode CE. The first conductive pattern CP1 may be electrically connected to the cathode electrode CE and reduce the resistance of the cathode electrode CE, thereby preventing or reducing the voltage drop of the cathode electrode CE.

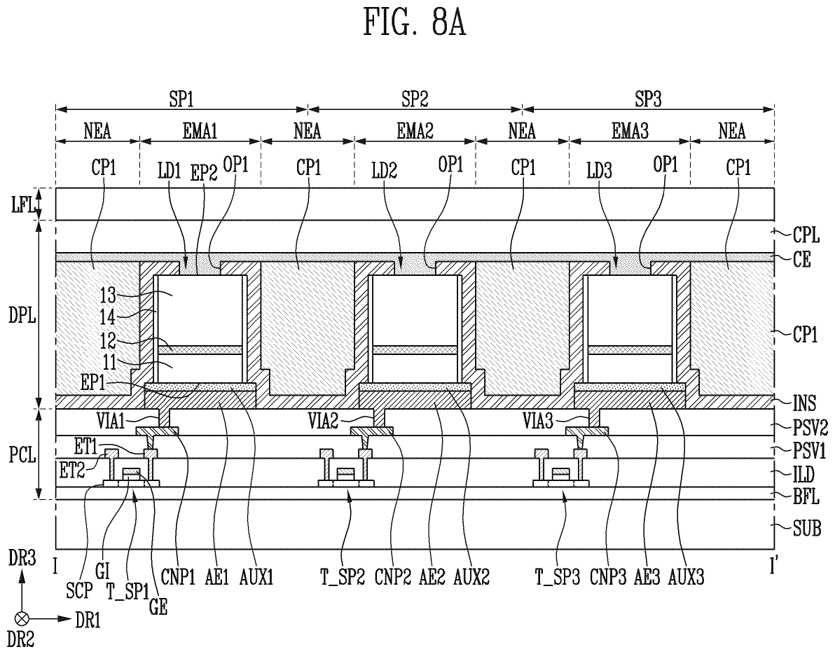

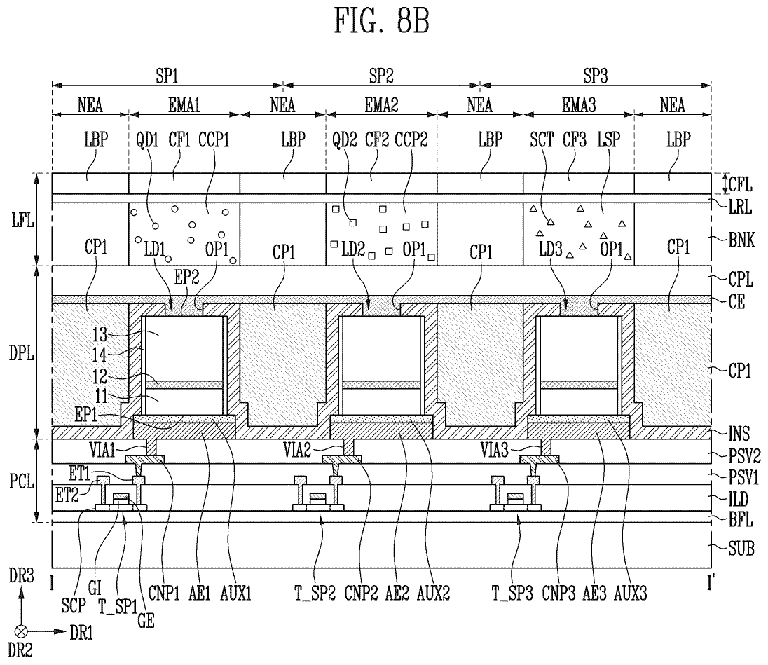

FIG. 8A and FIG. 8B are schematic cross-sectional diagrams corresponding to line I-I′ of FIG. 6, illustrating modified embodiments of FIG. 7 with respect to configurations on the display element layer DPL.

Referring to FIG. 8A and FIG. 8B, for convenience in explanation, the description duplicated with one or more embodiments of FIG. 7 will not be provided.

Referring to FIG. 8A, the light functional layer LFL may be arranged on the display element layer DPL. The light functional layer LFL may include a light extraction structure. The light extraction structure may be arranged on the capping layer CPL on the first light emitting element LD1, the second light emitting element LD2, and the third light emitting element LD3. The light extraction structure may play a role in improving the light efficiency of the light emitted from each of the first to third light emitting elements LD1 to LD3.

Referring to FIG. 8B, the light functional layer LFL may be arranged on the display element layer DPL. The light functional layer LFL may include the first and second light conversion patterns CCP1 and CCP2, the light scattering pattern LSP, a bank BNK, a low refractive layer LRL, and a color filter layer CFL.

The bank BNK may be arranged on the capping layer CPL in the non-light emitting area NEA. The bank BNK may include an opening that exposes the capping layer CPL positioned in the first to third light emitting areas EMA1 to EMA3. The opening of the bank BNK may define the formation position of each of the first and second light conversion patterns CCP1 and CCP2 and the light scattering pattern LSP. The bank BNK may be configured to include a light blocking substance to prevent or reduce light mixing between adjacent pixels PXL and the first to third sub-pixels SP1 to SP3. In one or more embodiments, the bank BNK may include an organic material. For example, the bank BNK may include organic insulating substances such as acrylic resins, epoxy-based resins, phenolic resins, polyamide-based resins, and polyimide-based resins.

It may be understood that first to third light emitting areas EMA1 to EMA3 and the non-light emitting areas NEA are defined by the bank BNK. The area where the bank BNK overlaps may correspond to the non-light emitting area NEA. The first and second light conversion patterns CCP1 and CCP2 and light scattering patterns LSP may be arranged within the opening of the bank BNK.

The first and second light conversion patterns CCP1 and CCP2 and the light scattering pattern LSP may include the color conversion particles and/or the scattering particles. The color conversion particles may convert incident light into light of a different color by changing the wavelength of the incident light. In some embodiments, the color conversion particles may scatter incident light. In one or more embodiments, the color conversion particles may be quantum dots. The scattering particles may scatter incident light.

In one or more embodiments, the first to third light emitting elements LD1 to LD3 may be configured to emit blue light. In such cases, the first light conversion pattern CCP1 may include first color conversion particles QD1 that are configured to convert blue light into red light. The second light conversion pattern CCP2 may include second color conversion particles QD2 that are configured to convert blue light into green light. The light scattering pattern LSP may include scattering particles SCT that scatter blue light to improve light emission efficiency. Accordingly, the first to third sub-pixels SP1 to SP3 may be provided as red sub-pixels, green sub-pixels, and blue sub-pixels, respectively. In one or more embodiments, at least one of the first and second light conversion patterns CCP1 and CCP2 and the light scattering pattern LSP may further include light conversion particles that convert blue light into white light.

The low refractive layer LRL may be arranged on the bank BNK, the first light conversion pattern CCP1, the second light conversion pattern CCP2, and the light scattering pattern LSP. The low refractive layer LRL may have a lower refractive index than the first and second light conversion patterns CCP1 and CCP2 and the light scattering pattern LSP. The low refractive layer LRL may be configured to refract or total reflect the light depending on the angle of incidence. The low refractive layer LRL may provide light that has passed through the first and second light conversion patterns CCP1 and CCP2 and the light scattering pattern LSP back to the first and second light conversion patterns CCP1 and CCP2 and the light scattering pattern LSP. Accordingly, the light conversion efficiency and light scattering efficiency of the first and second light conversion patterns CCP1 and CCP2 and the light scattering pattern LSP may be improved. In one or more embodiments, the low refractive layer LRL in an area corresponding to the third sub-pixel SP3 may not be provided.

The color filter layer CFL may be arranged on the low refractive layer LRL. The color filter layer CFL may include first to third color filters CF1 to CF3 and light blocking patterns LBP.

The first to third color filters CF1 to CF3 may overlap the first and second light conversion patterns CCP1 and CCP2 and the light scattering pattern LSP, respectively. Each of the first to third color filters CF1 to CF3 may selectively transmit light in the desired or suitable wavelength range. If the first sub-pixel SP1 is a red sub-pixel, the first color filter CF1 may include a red color filter. If the second sub-pixel SP2 is a green sub-pixel, the second color filter CF2 may include a green color filter. If the third sub-pixel SP3 is a blue sub-pixel, the third color filter CF3 may include a blue color filter. The first to third color filters CF1 and CF3 may have a higher refractive index than the low refractive layer LRL. However, embodiments are not limited thereto, and the first to third color filters CF1 to CF3 may have a refractive index lower than or equal to that of the low refractive layer LRL.

The light blocking patterns LBP may be arranged between the first to third color filters CF1 to CF3. It may be understood the first to third light emitting areas EMA1 to EMA3 (or the first to third light emission areas) and the non-light emitting area NEA are defined by the light blocking patterns LBP. An area that overlaps the light blocking patterns LBP may correspond to the non-light emitting area NEA.

In one or more embodiments, the light blocking patterns LBP may include at least one of one or more suitable types (kinds) of light blocking substances. In one or more embodiments, each of the light blocking patterns LBP may be provided in the form of multilayers in which at least two color filters of the first to third color filters CF1 to CF3 overlap. For example, each of the light blocking patterns LBP may be formed by overlapping the first to third color filters CF1 to CF3. As another example, the light blocking pattern LBP between the first and second color filters CF1 and CF2 among the light blocking patterns LBP may be formed as multilayers in which the first and second color filters CF1 and CF2 overlap, and the light blocking pattern LBP between the second and third color filters CF2 and CF3 among the light blocking patterns LBP may be formed as multilayers in which the second and third color filters CF2 and CF3 overlap. The light blocking pattern LBP between the first color filter CF1 and the third color filter CF3 of neighboring pixels PXL may be formed as multilayers in which the first and third color filters CF1 and CF3 overlap. As such, each of the first to third color filters CF1 to CF3 may extend to the non-light emitting area NEA to form the light blocking patterns LBP.

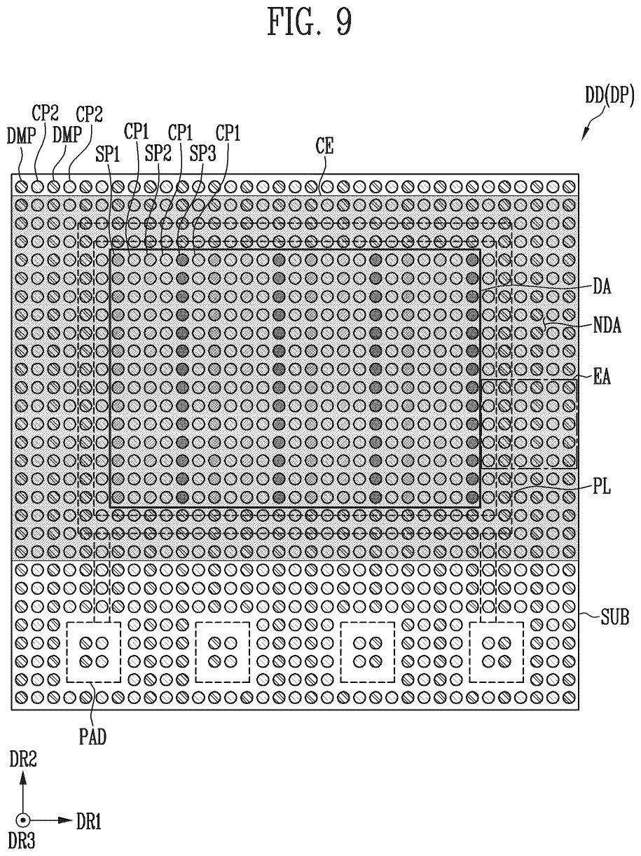

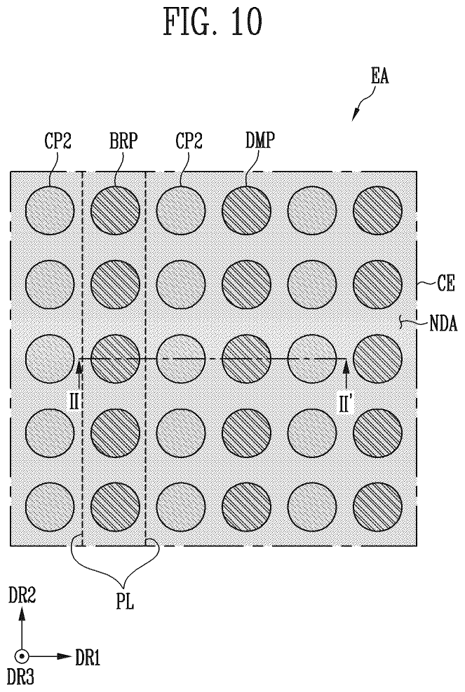

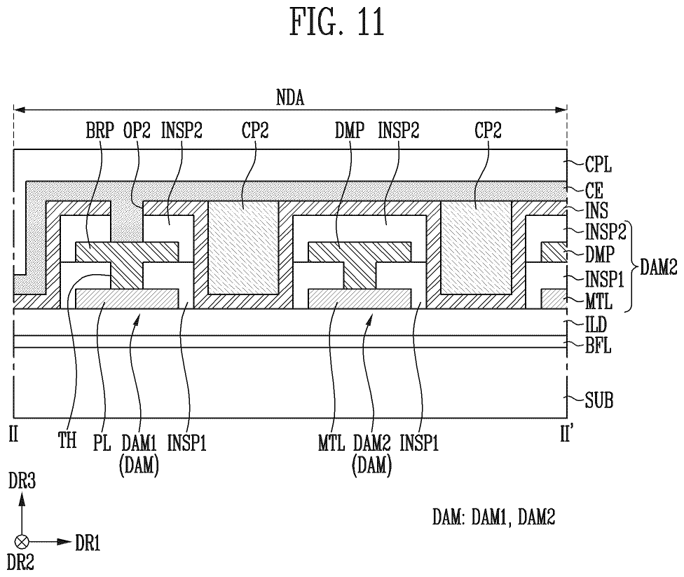

FIG. 9 is a schematic plan view illustrating a display device DD according to one or more embodiments, FIG. 10 is an enlarged schematic diagram illustrating an EA area of FIG. 9, and FIG. 11 is a schematic cross-sectional diagram taken along the line II-II′ of FIG. 10.

In FIG. 9 to FIG. 11, description will be set forth on that the display device DD is a micro-light emitting diode display device, including a subminiature light emitting diode (or micro-light emitting diode), but embodiments are not limited thereto.

In one or more embodiments, the display device DD may be applied to electronic devices such as wearable devices including watches, smart glasses, automotive electronic devices, tablet PCs, televisions, smartphones, or laptops, but the present disclosure is not limited thereto. According to one or more embodiments, the display device DD may also be applied to a transparent display device configured to transmit light.

Referring to FIG. 9 to FIG. 11, the display device DD (or the display panel DP) may include the substrate SUB and sub-pixels arranged on the substrate SUB. The substrate SUB may include the display area DA and the non-display area NDA.

The sub-pixels may be arranged in the display area DA. For example, the first sub-pixel SP1, the second sub-pixel SP2, and the third sub-pixel SP3 that are spaced and/or apart (e.g., spaced apart or separated) from each other may be arranged in the display area DA. The first light emitting element LD1 described in reference to FIG. 7 may be arranged in the first sub-pixel SP1, and the second light emitting element LD2 described in reference to FIG. 7 may be arranged in the second sub-pixel SP2, and the third light emitting element LD3 described in reference to FIG. 7 may be arranged in the third sub-pixel SP3.

In the display area DA, the first conductive pattern CP1 may be arranged between the first to third sub-pixels SP1 to SP3. The first conductive pattern CP1 may be connected to the cathode electrode CE to reduce the resistance of the cathode electrode CE.

The cathode electrode CE may be arranged across a portion of the display area DA and the non-display area NDA. The cathode electrode CE may be provided in the form of a plate in the display device DD (or the display panel DP).

In the non-display area NDA, the power line PL, a second conductive pattern CP2, a dummy pattern DMP, and a pad PAD may be arranged.

The power line PL may have a closed-loop shape that surrounds an edge of the display area DA in the non-display area NDA, but the present disclosure is not limited thereto. The power line PL may be electrically connected to the corresponding pad PAD among a plurality of pads PAD. In some embodiments, the power line PL may be electrically connected to the cathode electrode CE. In one or more embodiments, the power line PL may be formed by substantially the same process as one of the conductive layers that are arranged in the pixel circuit layer (see “PCL” in FIG. 7) of the display area DA. For example, the power line PL may be formed by substantially the same process as the conductive layer (or the second gate conductive layer) including the first and second terminals ET1 and ET2 described in reference to FIG. 7. Thereby, the power line PL and the first and second terminals ET1 and ET2 may be provided in substantially the same layer and include the same material.

The pads PAD may supply (or transmit) drive powers and signals to drive the first to third sub-pixels SP1 to SP3 and/or internal circuit units arranged in the display area DA. At least one of the pads PAD may be electrically connected to the power line PL to supply the second power voltage to the power line PL. Accordingly, the second power voltage may be supplied to the cathode electrode CE connected by the power line PL. Of the pads PAD, a pad PAD that is electrically connected to the power line PL may be integrated with the power line PL.

A bridge pattern BRP may be arranged on the power line PL. The bridge pattern BRP may be arranged on the power line PL with a first insulating pattern INSP1 interposed therebetween. The bridge pattern BRP may be electrically connected to the power line PL via a through-hole TH of the first insulating pattern INSP1. The bridge pattern BRP may be positioned between the power line PL and the cathode electrode CE to be utilized as a connection referring to electrically connect the power line PL and the cathode electrode CE. When viewed on a plane, the bridge pattern BRP may overlap with the power line PL.

A second insulating pattern INSP2 may be arranged on the bridge pattern BRP. The second insulating pattern INSP2 may be partially opened to expose one area of the bridge pattern BRP. The cathode electrode CE may be electrically connected to the bridge pattern BRP through the opening of the second insulating pattern INSP2.

The second conductive pattern CP2 may be arranged between adjacent dummy patterns DMP in the non-display area NDA. The second conductive pattern CP2 may be arranged to be spaced and/or apart (e.g., spaced apart or separated) from the dummy patterns DMP. The second conductive pattern CP2 may be formed by substantially the same process as the first conductive pattern CP1 arranged in the display area DA, provided in substantially the same layer, and include the same materials. For example, the first conductive pattern CP1 and the second conductive pattern CP2 may be composed of copper. The first conductive pattern CP1 and the second conductive pattern CP2 may have configurations arranged in the display area DA and the non-display area NDA in order to secure a pattern density throughout the display device DD (or the display panel DP). The second conductive pattern CP2 may be electrically connected to the cathode electrode CE in the non-display area NDA and reduce the resistance of the cathode electrode CE, thereby preventing or reducing the voltage drop of the cathode electrode CE.

A dummy pattern DMP may be positioned in the non-display area NDA to be arranged between adjacent second conductive patterns CP2. For example, a single second conductive pattern CP2 may be arranged between two adjacent dummy patterns DMP. The dummy pattern DMP and the second conductive pattern CP2 may be spaced and/or apart (e.g., spaced apart or separated) from each other.

In one or more embodiments, the dummy pattern DMP may be formed of one of the conductive layers arranged in the pixel circuit layer PCL in the display area DA. For example, the dummy pattern DMP may be formed of, but the present disclosure is not limited thereto, the conductive layer (or a source-drain conductive layer) substantially identical to the first to third connection patterns CNP1 to CNP3 described in reference to FIG. 7. According to one or more embodiments, the dummy pattern DMP may be formed of different conductive layers of the pixel circuit layer PCL.

The dummy pattern DMP may be arranged to be spaced and/or apart (e.g., spaced apart or separated) from the bridge pattern BRP arranged on the power line PL. The dummy pattern DMP may be formed by substantially the same process as the bridge pattern BRP. Accordingly, the dummy patterns DMP and the bridge pattern BRP may be provided in substantially the same layers and include the same materials.

A metal layer MTL may be arranged on the bottom of the dummy pattern DMP. The metal layer MTL may be formed of a conductive layer different from one of the conductive layers arranged in the pixel circuit layer PCL of the display area DA. For example, the metal layer MTL may be formed of the same conductive layer (or a second gate conductive layer) as the first and second terminals ET1 and ET2 described in reference to FIG. 7, but the present disclosure is not limited thereto. In some embodiments, the metal layer MTL may be formed of the same layer as the power line PL.

Between the dummy pattern DMP and the metal layer MTL, the first insulating pattern INSP1 may be arranged. The first insulating pattern INSP1 may be formed by substantially the same process as the first passivation layer PSV1 arranged in the pixel circuit layer PCL of the display area DA. The first insulating pattern INSP1 may include the through-hole TH that exposes one area of the metal layer MTL. Through the through-hole TH, the dummy pattern DMP and the metal layer MTL may be electrically connected.

On the dummy pattern DMP, the second insulating pattern INSP2 may be arranged. The second insulating pattern INSP2 may be formed by substantially the same process as the second passivation layer PSV2 arranged in the pixel circuit layer PCL of the display area DA. The second insulating pattern INSP2 may be arranged on the dummy pattern DMP and cover the dummy pattern DMP.

A plurality of dam structures DAM may be arranged in the non-display area NDA. The dam structures DAM may define the formation position of the second conductive pattern CP2. For example, the second conductive pattern CP2 may be formed between the two adjacent dam structures DAM.

Each of the dam structures DAM may be provided as a multilayer, including at least one insulating patterns provided and/or formed on the inter-layer dielectric layer ILD and at least one conductive layer. For example, the dam structures DAM may be provided as a multilayer structure laminated in the order of the metal layer MTL, the first insulating pattern INSP1, the dummy pattern DMP, and the second insulating pattern INSP2 along the third direction DR3.

At least one of the dam structures DAM may be provided as a multilayer structure in which the power line PL, the first insulating pattern INSP1, the bridge pattern BRP, and the second insulating pattern INSP2 are sequentially laminated along the third direction DR3. Hereinafter, for convenience of explanation, a dam structure DAM including the bridge pattern BRP is referred to as a first dam structure DAM1 and a dam structure DAM including the dummy pattern DMP is referred to as a second dam structure DAM2. When arbitrarily referring to one or more dam structures DAM of the first dam structures DAM1 and the second dam structures DAM2, or comprehensively referring to two or more dam structures DAM, they will be referred to as “a dam structure DAM” or “dam structures DAM”.

The element insulating layer INS may be arranged on the dam structures DAM. The element insulating layer INS may be commonly provided in the non-display area NDA and the display area DA. In the display area DA, the element insulating layer INS may be arranged on the light emitting elements LD1, LD2, and LD3 and the second passivation layer PSV2, and in the non-display area NDA, the element insulating layer INS may be arranged on the dam structures DAM and the inter-layer dielectric layer ILD. The element insulating layer INS may include a second opening OP2 exposing one area of the bridge pattern BRP. The second opening OP2 of the element insulating layer INS may correspond to the opening of the second insulating pattern INSP2 that exposes one area of the bridge pattern BRP.

Each of the foregoing dam structures DAM may be arranged to be spaced and/or apart (e.g., spaced apart or separated) from adjacent dam structures DAM. For example, the two adjacent dam structures DAM may be spaced and/or apart (e.g., spaced apart or separated) at a certain interval. In one or more embodiments, the second conductive pattern CP2 may be arranged on the element insulating layer INS between the two adjacent dam structures DAM. The second conductive pattern CP2 may be arranged on the element insulating layer INS in the form of filling a space between the adjacent dam structures DAM.

The second conductive pattern CP2 may be formed between the adjacent dam structures DAM in the non-display area NDA through the CMP process. The second conductive pattern CP2 may be formed by substantially the same process as the first conductive pattern CP1 and have a flat upper surface. The upper surface of the second conductive pattern CP2 may be in a colinear position with the upper surface of the element insulating layer INS that is arranged on the dam structures DAM in the first direction DR1.

The cathode electrode CE may be formed on the second conductive pattern CP2 and the element insulating layer INS, and the capping layer CPL may be formed on the cathode electrode CE. The cathode electrode CE and the capping layer CPL may be commonly provided in the display area DA and the non-display area NDA.

In the non-display area NDA, the second conductive pattern CP2 may be physically and/or electrically connected to the cathode electrode CE by direct contact with the cathode electrode CE. The second conductive pattern CP2 may be electrically connected to the cathode electrode CE so that the resistance of the cathode electrode CE may be reduced, thereby preventing or reducing the voltage drop of the cathode electrode CE.

According to one or more embodiments described herein, as the dam structures DAM that define the formation position of the second conductive pattern CP2 in the non-display area NDA are formed of insulating layers and conductive layers arranged in the pixel circuit layer PCL of the display area DA, the process for forming a separate structure defining the formation position of the second conductive pattern CP2 may not be provided, thereby simplifying the manufacturing process of the display device DD.

Further, according to one or more embodiments described herein, at least some of the dam structures DAM may be directly connected to the cathode electrode CE to reduce the resistance of the cathode electrode CE. As a result, the reliability of the display device DD may be improved by preventing or reducing the voltage drop of the cathode electrode CE.

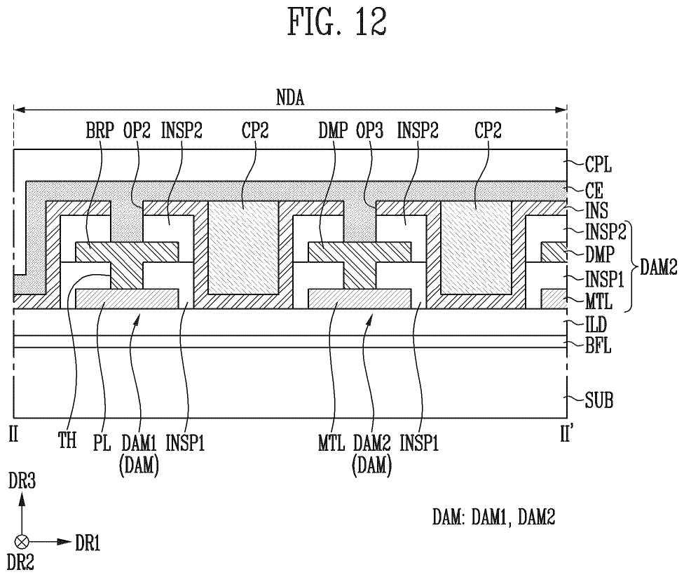

FIG. 12 to FIG. 14 are schematic cross-sectional diagrams corresponding to line II-II′ of FIG. 10, illustrating a portion of a non-display area NDA of a display device DD according to one or more embodiments. In particular, FIG. 12 to FIG. 14 may be cross-sectional diagrams illustrating modified embodiments of FIG. 11 in relation to the dam structures DAM.

In FIG. 12 to FIG. 14, for convenience of explanation, the description duplicated with one or more embodiments of FIG. 11 will not be provided.

Referring to FIG. 10 and FIG. 12, the element insulating layer INS arranged on the dam structures DAM in the non-display area NDA may be partially opened to expose one area of each of the dam structures DAM. For example, the element insulating layer INS may be partially opened to include the second opening OP2 exposing one area of the bridge pattern BRP in the first dam structure DAM1 and a third opening OP3 exposing one area of the dummy pattern DMP in the second dam structure DAM2. At this time, the second insulating pattern INSP2 arranged on the dummy pattern DMP in the second dam structure DAM2 may expose one area of the dummy pattern DMP by including an opening corresponding to the third opening OP3 of the element insulating layer INS.

Each of the dam structures DAM may be electrically connected to the cathode electrode CE through the opening corresponding to the element insulating layer INS. For example, the bridge pattern BRP of the first dam structure DAM1 may be physically and/or electrically connected to the cathode electrode CE through the second opening OP2 of the element insulating layer INS, and the dummy pattern DMP of the second dam structure DAM2 may be physically and/or electrically connected to the cathode electrode CE through the third opening OP3 of the element insulating layer INS.

As the dam structures DAM are electrically connected to the cathode electrode CE in the non-display area NDA, it is possible to further prevent or reduce the voltage drop of the cathode electrode CE by reducing the resistance of the cathode electrode CE.

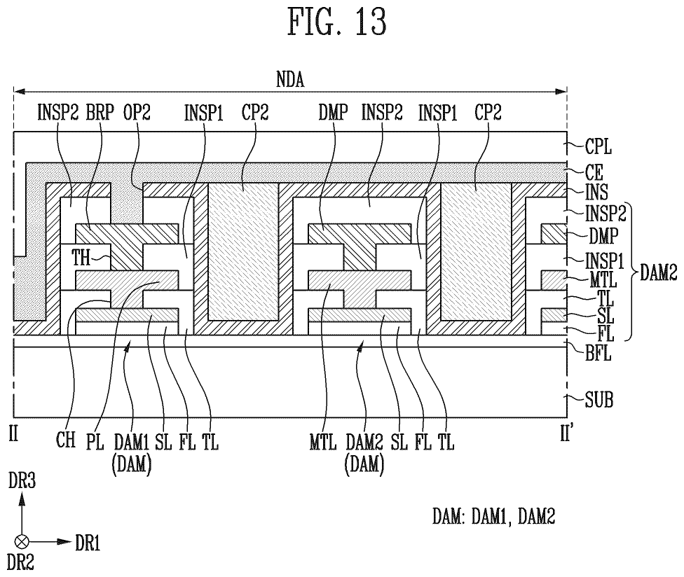

Referring to FIG. 10 and FIG. 13, each of the dam structures DAM may be formed of multilayers arranged on the buffer layer BFL. For example, the first dam structure DAM1 may have a multilayer structure including a first layer FL, a second layer SL, a third layer TL, the power line PL, the first insulating pattern INSP1, the bridge pattern BRP, and the second insulating pattern INSP2 that are sequentially laminated from one side of the buffer layer BFL along the third direction DR3. The second dam structure DMA2 may have a multilayer structure including the first layer FL, the second layer SL, the third layer TL, the metal layer MTL, the first insulating pattern INSP1, the dummy pattern DMP, and the second insulating pattern INSP2 that are sequentially laminated from one side of the buffer layer BFL along the third direction DR3.

The first layer FL may be configured by substantially the same process as the gate insulating layer (see “GI” in FIG. 7) arranged in the pixel circuit layer (see “PCL” in FIG. 7) in the display area (see “DA” in FIG. 9). The first layer FL and the gate insulating layer GI may be provided in substantially the same layer and include the same material.

The second layer SL may be formed of the same conductive layer (or a first gate conductive layer) as the gate electrode (see “GE” in FIG. 7) arranged in the pixel circuit layer PCL of the display area DA. The second layer SL and the gate electrode GE may be formed by substantially the same process, provided in substantially the same layer, and include the same material.

The third layer TL may be configured by substantially the same process as the inter-layer dielectric layer ILD arranged in the pixel circuit layer PCL of the display area DA. The third layer TL and the inter-layer dielectric layer ILD may be provided in substantially the same layer and include the same material. The third layer TL may include a contact hole CH that exposes one area of the second layer SL. In the first dam structure DAM1, the second layer SL may be electrically connected to the power line PL arranged on the third layer TL through the contact hole CH in the third layer TL. In the second dam structure DAM2, the second layer SL may be electrically connected to the metal layer MTL arranged on the third layer TL through the contact hole CH in the third layer TL.

In one or more embodiments, the first layer FL and the third layer TL may be inorganic insulating patterns with insulating properties, and the second layer SL may be patterns with conductivity.

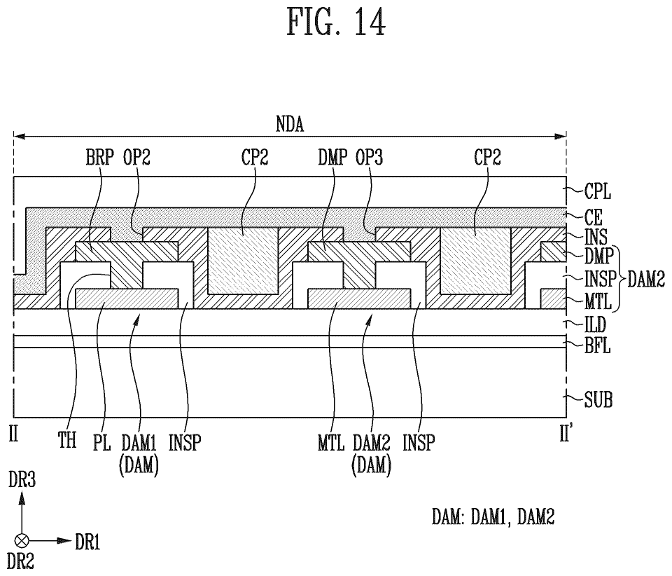

Referring to FIG. 10 and FIG. 14, the first dam structure DAM1 may include the power line PL, the insulating pattern INSP, and the bridge pattern BRP that are sequentially laminated along the third direction DR3 from one side of the inter-layer dielectric layer ILD. The second dam structure DAM2 may include the metal layer MTL, the insulating pattern INSP, and the dummy pattern DMP that are sequentially laminated from one side of the inter-layer dielectric layer ILD along the third direction DR3. The insulating pattern INSP may be formed by substantially the same process as the first passivation layer PSV1 arranged in the pixel circuit layer (see “PCL” in FIG. 7) in the display area (see “DA” in FIG. 9). The insulating pattern INSP and the first passivation layer PSV1 may be arranged in substantially the same layer and include the same material.

In the first dam structure DAM1, the bridge pattern BRP may be electrically connected to the cathode electrode CE through the second opening OP2 of the element insulating layer INS. In the second dam structure DAM2, the dummy pattern DMP may be electrically connected to the cathode electrode CE through the third opening OP3 of the element insulating layer INS.

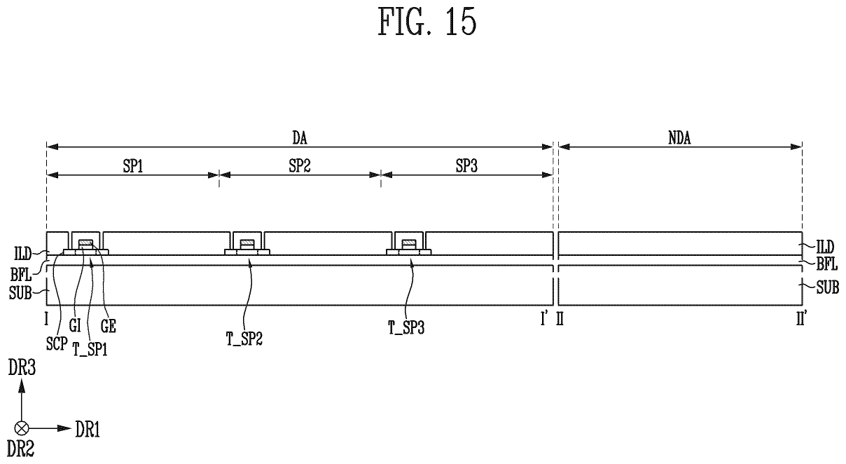

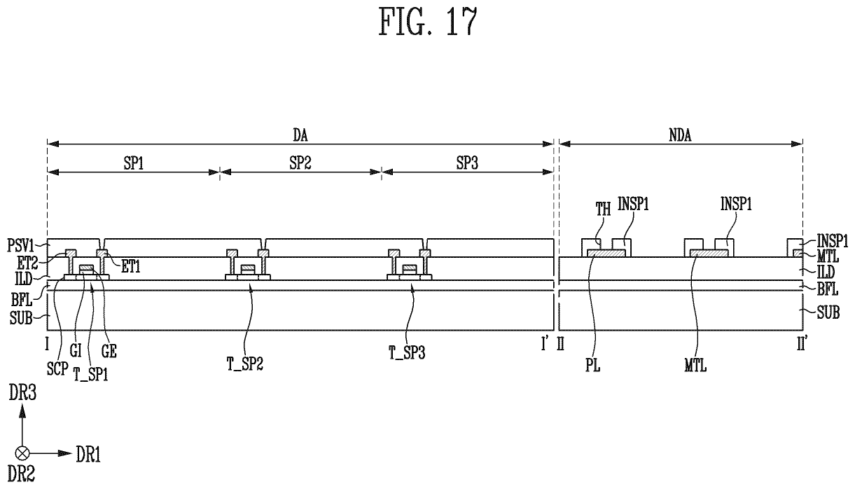

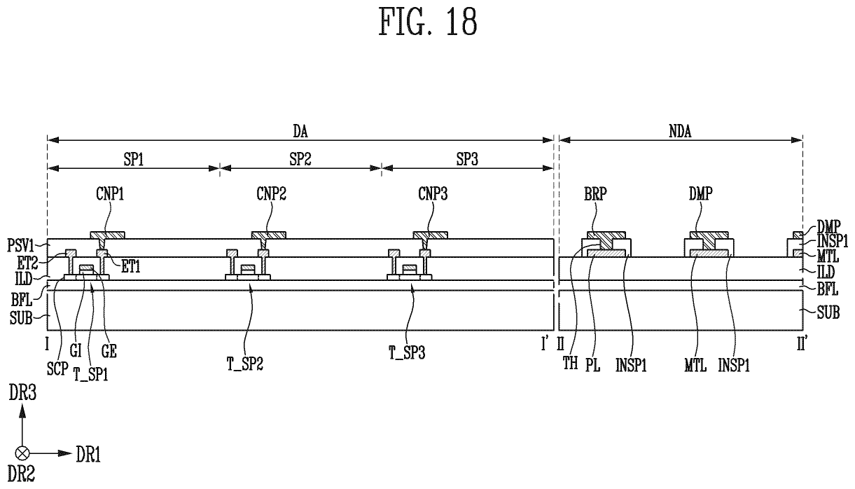

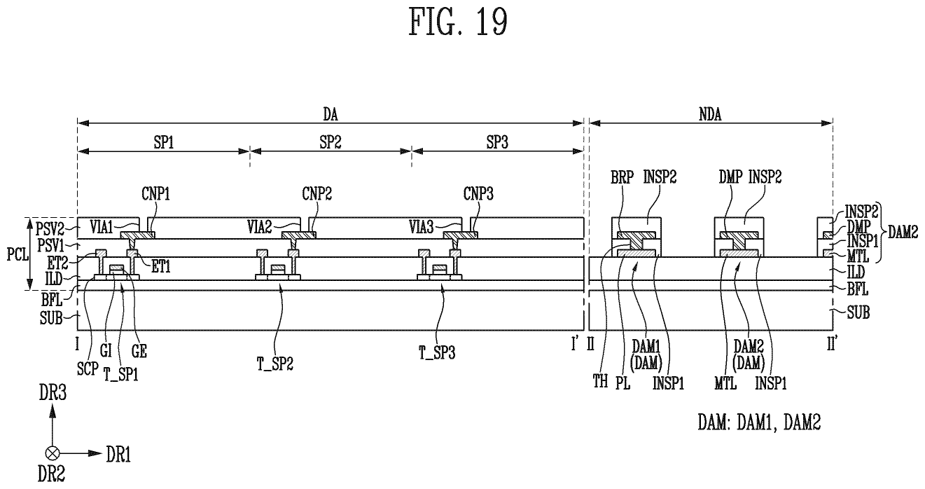

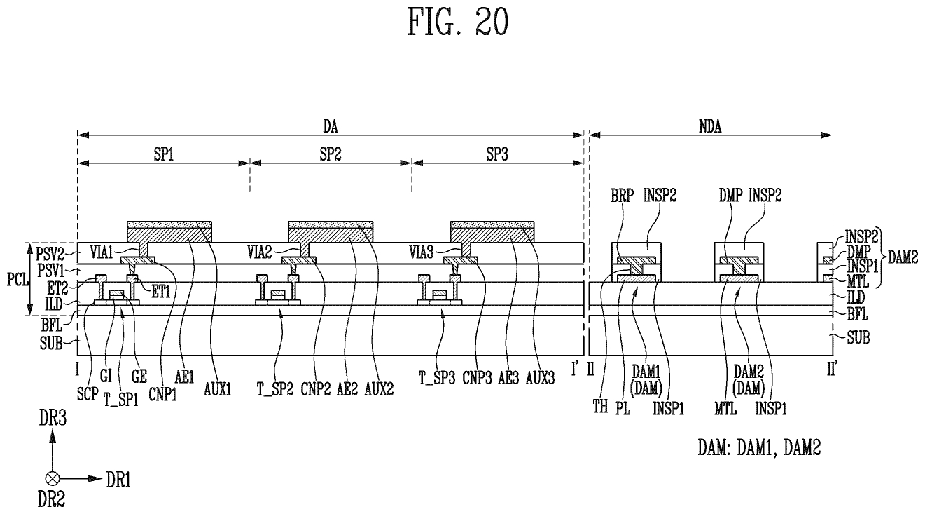

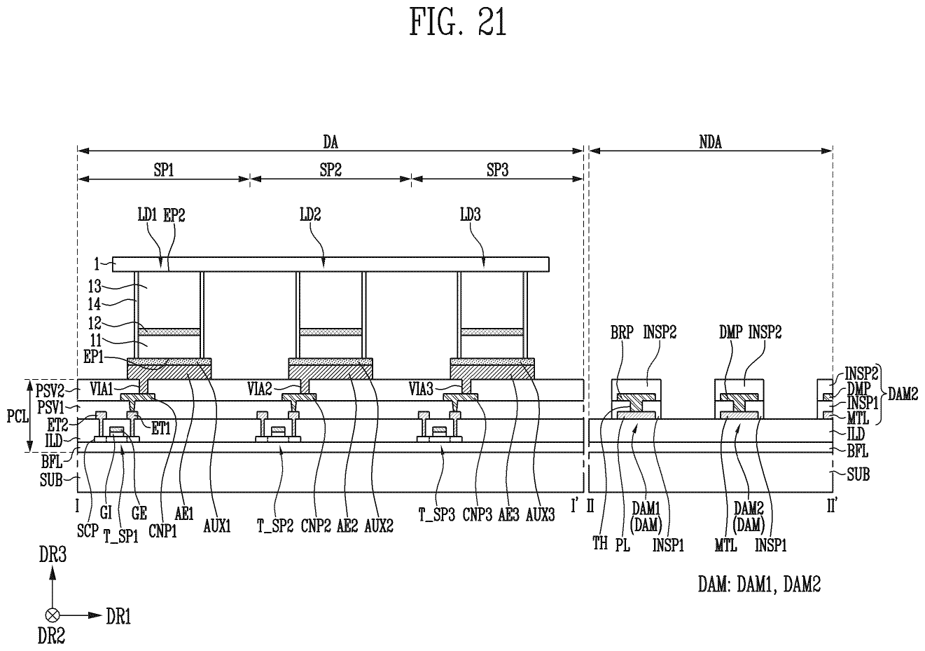

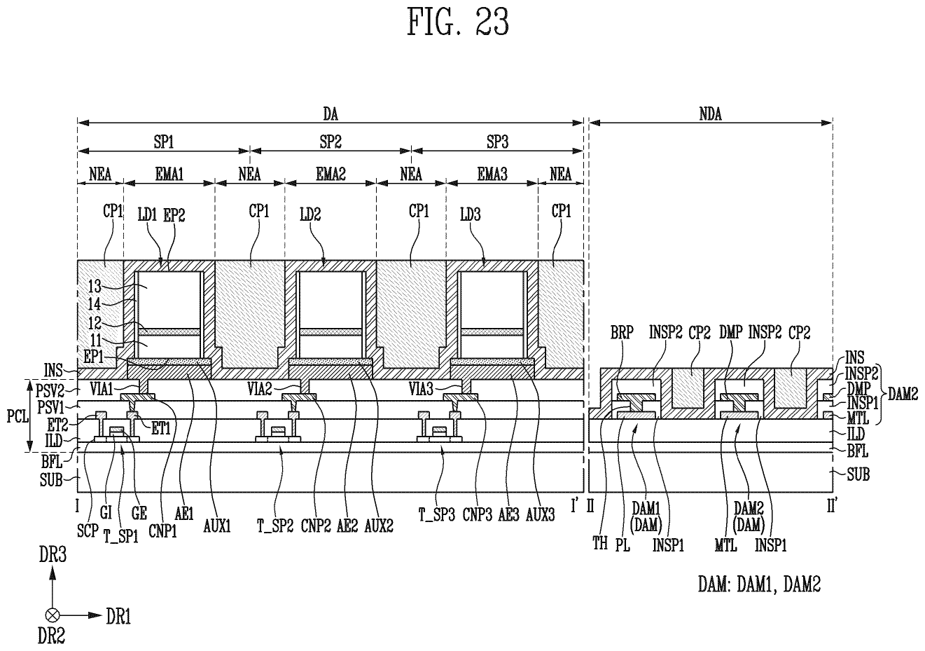

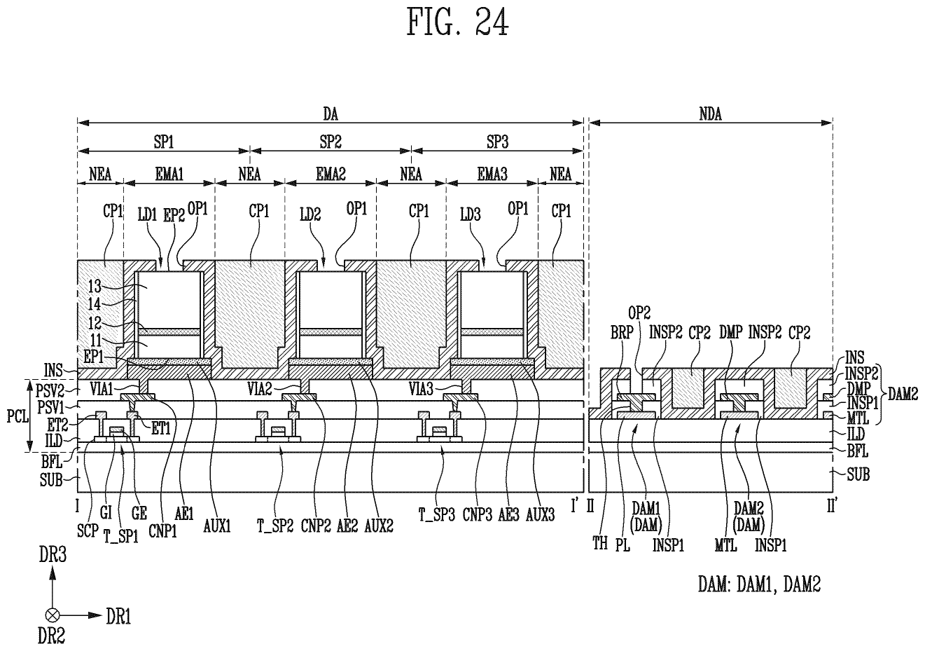

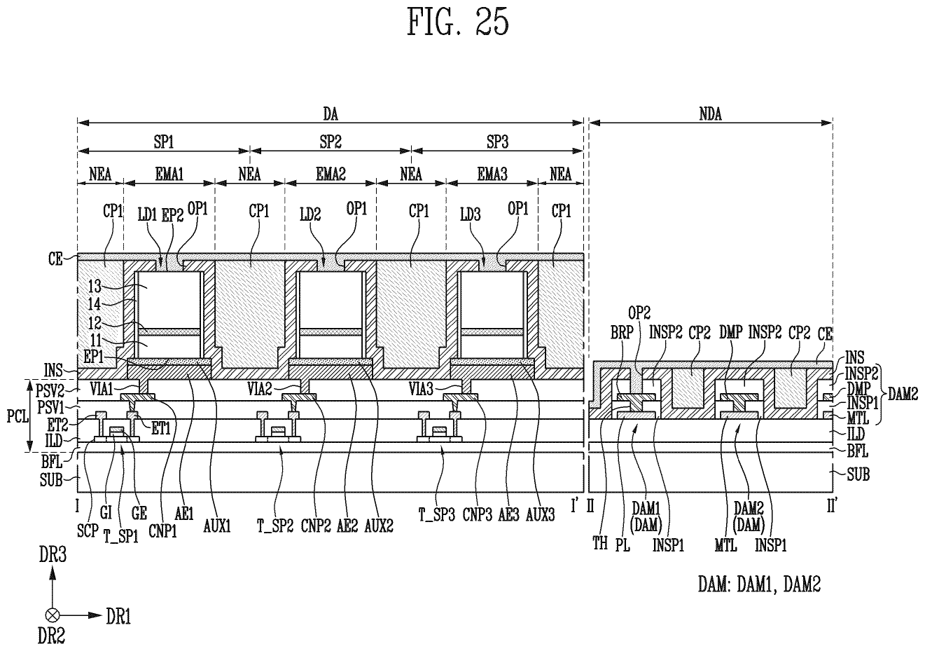

FIG. 15 to FIG. 25 are schematic cross-sectional diagrams illustrating a method of manufacturing a display device DD according to one or more embodiments.

In one or more embodiments, though manufacturing steps of the display device DD are described as being performed sequentially according to the cross-sectional diagrams, it is apparent, unless the technical scope of the disclosure is changed, that some of the steps that are shown to be performed in succession are performed concurrently (e.g., simultaneously), the order of each (e.g., act or task) step is changed, some steps are omitted, or other steps are included between each (e.g., act or task) step.

In FIG. 15 to FIG. 25, for convenience in explanation, the description duplicated with one or more embodiments preceding will not be provided.

Referring to FIG. 15, the buffer layer BFL and the inter-layer dielectric layer ILD are formed on the substrate SUB commonly provided in the display area DA and the non-display area NDA.

In the display area DA, between the buffer layer BFL and the inter-layer dielectric layer ILD, the transistor T_SP1 of the first sub-pixel SP1, the transistor T_SP2 of the second sub-pixel SP2, and the transistor T_SP3 of the third sub-pixel SP3 may be formed. Each of the transistor T_SP1 of the first sub-pixel SP1, the transistor T_SP2 of the second sub-pixel SP2, and the transistor T_SP3 of the third sub-pixel SP3 may include the semiconductor pattern SCP and the gate electrode GE.

In the display area DA, the inter-layer dielectric layer ILD may include a partially opened area to expose one area of the semiconductor pattern SCP of each of the transistor T_SP1 of the first sub-pixel SP1, the transistor T_SP2 of the second sub-pixel SP2, and the transistor T_SP3 of the third sub-pixel SP3.

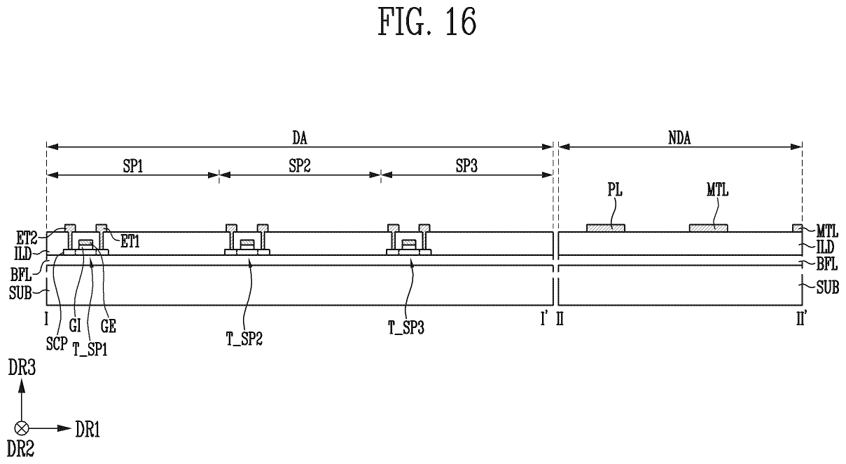

Referring to FIG. 15 and FIG. 16, the first terminal ET1 and the second terminal ET2 are formed on the inter-layer dielectric layer ILD of the display area DA, and the power line PL and the metal layer MTL are formed on the inter-layer dielectric layer ILD in the non-display area NDA.

The first terminal ET1, the second terminal ET2, the power line PL, and the metal layer MTL may be formed by substantially the same process, provided in substantially the same layer, and include the same material.

The first terminal ET1 and second terminal ET2 may be arranged to be spaced and/or apart (e.g., spaced apart or separated) from each other in the display area DA, and the power line PL and metal layer MTL may be arranged to be spaced and/or apart (e.g., spaced apart or separated) from each other in the non-display area DA. The power line PL may be around (e.g., surround) an edge of the display area DA.

Referring to FIG. 15 to FIG. 17, the first passivation layer PSV1 is formed on the first and second terminals ET1 and ET2 and the inter-layer dielectric layer ILD in the display area DA, and the first insulating pattern INSP1 is formed on the power line PL and the metal layer MTL in the non-display area NDA. The first passivation layer PSV1 and the first insulating pattern INSP1 may be formed by substantially the same process.

The first passivation layer PSV1 may include an area partially opened to expose one area of the first terminal ET1.

The first insulating pattern INSP1 may include the through-hole TH exposing one area of each of the power line PL and the metal layer MTL.

Referring to FIG. 15 to FIG. 18, the first to third connection patterns CNP1 to CNP3 are formed on the first passivation layer PSV1 of the display area DA, and the bridge pattern BRP and the dummy pattern DMP are formed on the first insulating pattern INSP1 in the non-display area NDA. The first to third connection patterns CNP1 to CNP3, the bridge pattern BRP, and the dummy pattern DMP may be formed by substantially the same process.

The first to third connection patterns CNP1 to CNP3, the bridge pattern BRP, and the dummy pattern DMP may be formed of the source-drain conductive layer.

In the display area DA, the first to third connection patterns CNP1 to CNP3 may be arranged to be spaced and/or apart (e.g., spaced apart or separated) from each other. The first connection pattern CNP1 may be electrically connected to the first terminal ET1 of the transistor T_SP1 of the first sub-pixel SP1, the second connection pattern CNP2 may be electrically connected to the first terminal ET1 of the transistor T_SP2 of the second sub-pixel SP2, and the third connection pattern CNP3 may be electrically connected to the first terminal ET1 of the transistor T_SP3 of the third sub-pixel SP3.

In the non-display area NDA, the bridge pattern BRP and the dummy pattern DMP may be arranged to be spaced and/or apart (e.g., spaced apart or separated) from each other. The bridge pattern BRP may be electrically connected to the power line PL via the through-hole TH of the first insulating pattern INSP1, and the dummy pattern DMP may be electrically connected to the metal layer MTL via the through-hole TH of the first insulating pattern INSP1.

Referring to FIG. 15 to FIG. 19, the second passivation layer PSV2 is formed on the first to third connection patterns CNP1 to CNP3 and the first passivation layer PSV1 in the display area DA, and the second insulating pattern INSP2 is formed on the bridge pattern BRL and the dummy pattern DMP in the non-display area NDA. The second passivation layer PSV2 and the second insulating pattern INSP2 may be formed by substantially the same process.

The second passivation layer PSV2 may include partially opened areas to expose one area of each of the first to third connection patterns CNP1 to CNP3. The second insulating pattern INSP2 on the bridge pattern BRP and the dummy pattern DMP may cover each of the bridge pattern BRP and the dummy pattern DMP.

The power line PL, the first insulating pattern INSP1, the bridge pattern BRP, and the second insulating pattern INSP2 that are sequentially laminated along the third direction DR3 from one side of the inter-layer dielectric layer ILD in the non-display area NDA may form the first dam structure DAM1. In some embodiments, the metal layer MTL, the first insulating pattern INSP1, the dummy pattern DMP, and the second insulating pattern INSP2 that are sequentially laminated along the third direction DR3 from one side of the inter-layer dielectric layer ILD in the non-display area NDA may form the second dam structure DMA2.

Referring to FIG. 15 to FIG. 20, the first anode electrode AE1, the second anode electrode AE2, and the third anode electrode AE3 are formed on the second passivation layer PSV2 of the display area DA. The first anode electrode AE1, the second anode electrode AE2, and the third anode electrode AE3 may be arranged on the second passivation layer PSV2 to be spaced and/or apart (e.g., spaced apart or separated) from each other.

Successively, the first auxiliary electrode AUX1 is formed on the first anode electrode AE1, the second auxiliary electrode AUX2 on the second anode electrode AE2, and the third auxiliary electrode AUX3 on the third anode electrode AE3.

Referring to FIG. 15 to FIG. 21, the first light emitting element LD1, the second light emitting element LD2, and the third light emitting element LD3 separated from a growth substrate and transferred to a transfer base material 1 are arranged at a set or predetermined position in the display area DA. For example, the transfer base material 1, on which the first to third emitting elements LD1 to LD3 are transferred to have each of the first and third light emitting elements LD1 to LD3 oriented toward the anode electrode to which the first end EP1 corresponds, is arranged in the display area DA. Each of the first to third light emitting elements LD1 to LD3 may include a vertical light emitting laminate including the first semiconductor layer 11, the active layer 12, and the second semiconductor layer 13 that are sequentially arranged along the third direction DR3 in a direction from the anode electrode to the transfer base material 1, and the insulating film 14 around (e.g., surrounding) an outer peripheral surface of the vertical light emitting laminate.

The transfer base material 1 may be a light permeable substrate including sapphire, glass, and polyimide. Accordingly, the transfer base material 1 may be to transmit laser light irradiated from the upper and/or lower portion. A sacrificial layer may be provided between the transfer base material 1 and the first to third light emitting elements LD1 to LD3. Selected as the sacrificial layer may be substances that are easily peeled off by the irradiated laser among substances having adhesiveness (or cohesiveness). When the bonding electrode and anode electrode of the first to third light emitting elements LD1 to LD3 are bonded and then the laser is irradiated to the top of the transfer base material 1, the sacrificial layer and the first to third light emitting elements LD1 to LD3 may be physically separated. For instance, the sacrificial layer may lose its adhesive function if (e.g., when) irradiated by the laser. Accordingly, the second end EP2 of each of the first to third light emitting elements LD1 to LD3 may be exposed to the outside.

Referring to FIG. 15 to FIG. 22, the element insulating layer INS is formed across the display area DA and the non-display area NDA.

In the display area DA, the element insulating layer INS may be arranged on the first to third light emitting elements LD1 to LD3 and the second passivation layer PSV2. In the non-display area NDA, the element insulating layer INS may be arranged on the first and second dam structures DAM1 and DAM2 and the inter-layer dielectric layer ILD. The element insulating layer INS may be an inorganic insulating layer including inorganic materials.

Referring to FIG. 15 to FIG. 23, after applying a base conductive material layer that is composed of copper over the whole area of the display area DA and the non-display area NDA, through a planarization process, e.g., a chemical mechanical polishing (CMP) process, the first conductive pattern CP1 is formed in the display area DA, and the second conductive pattern CP2 is formed in the non-display area NDA.

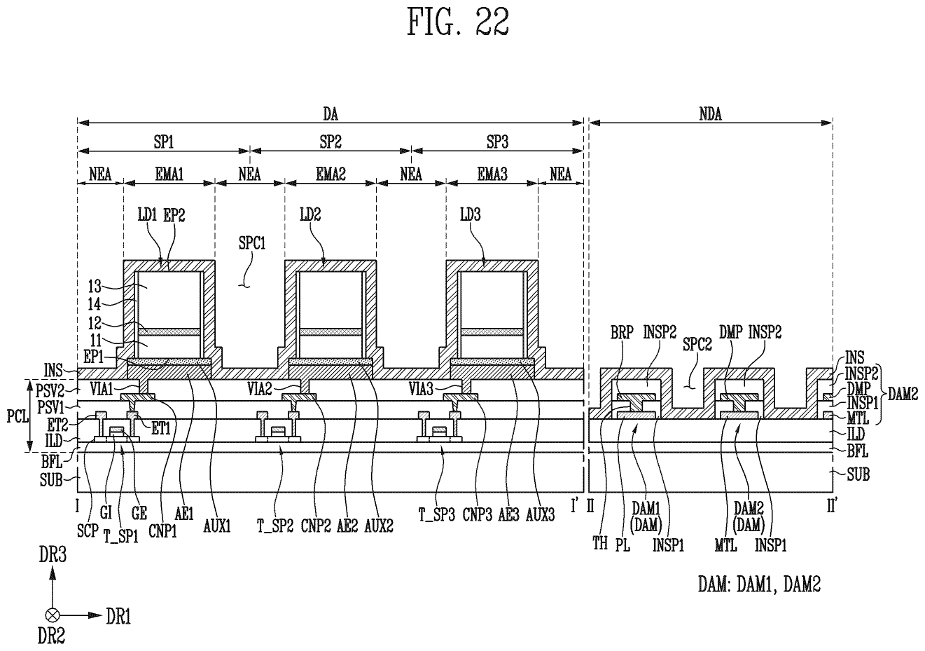

The first conductive pattern CP1 may be provided in the form of filling a space (see “SPC1” in FIG. 22) between adjacent light emitting elements in the display area DA, and the second conductive pattern CP2 may be provided in the form of filling a space (see “SPC2” in FIG. 22) between adjacent dam structures DAM in the non-display area NDA.

Upper surfaces of the first conductive pattern CP1 and the second conductive pattern CP2 may be planarized by the planarization process. The upper surfaces of each of the first and second conductive patterns CP1 and CP2 may be in a colinear position with the upper surface of the element insulating layer INS in the first direction DR1.

Referring to FIG. 15 to FIG. 24, a photolithography process using a mask is proceeded to remove a portion of the element insulating layer INS.

The element insulating layer INS may include the first opening OP1 exposing the second semiconductor layer 13 positioned at the second end EP2 of each of the first to third light emitting elements LD1 to LD3 in the display area DA. In some embodiments, the element insulating layer INS may include the second opening OP2 that exposes a portion of the bridge pattern BRP of the first dam structure DAM1 in the non-display area NDA. At this time, a portion of the second insulating pattern INSP2 of the first dam structure DAM1 arranged at the bottom of the element insulating layer INS may be removed to correspond to the second opening OP2 of the element insulating layer INS. Thereby, the bridge pattern BRP in the first dam structure DAM1 may be exposed to the outside.

Referring to FIG. 15 to FIG. 25, the cathode electrode CE is formed on the element insulating layer INS including the first opening OP1 and the second opening OP2.

In the display area DA, the cathode electrode CE may be electrically connected to each of the first to third light emitting elements LD1 to LD3 through the first opening OP1 of the element insulating layer INS. The cathode electrode CE may be arranged directly on the first conductive pattern CP1 and electrically connected to the first conductive pattern CP1.

In the non-display area NDA, the cathode electrode CE may be physically and/or electrically connected to the bridge pattern BRP through the second opening OP2 of the element insulating layer INS. The cathode electrode CE may be electrically connected to the power line PL supplied with the second power voltage through the bridge pattern BRP. Thereby, the second power voltage may be supplied to the cathode electrode CE.

As the cathode electrode CE is electrically connected to the first conductive pattern CP1 in the display area DA and electrically connected to the second conductive pattern CP2 in the non-display area NDA, the resistance of the cathode electrode CE may be reduced, thereby preventing or reducing the voltage drop of the cathode electrode CE.

Thereafter, the capping layer (see “CPL” in FIG. 7) may be formed on the cathode electrode CE.

According to one or more embodiments described herein, while the first conductive pattern CP1 and the second conductive pattern CP2 are arranged to secure a pattern density across the non-display area NDA and the display area DA, by forming the dam structure DAM defining the formation position of the second conductive pattern CP2 in the non-display area NDA as the insulating layer and the conductive layer arranged in the pixel circuit layer PCL of the display area DA, a separate process for forming the dam structure DAM may not be provided.

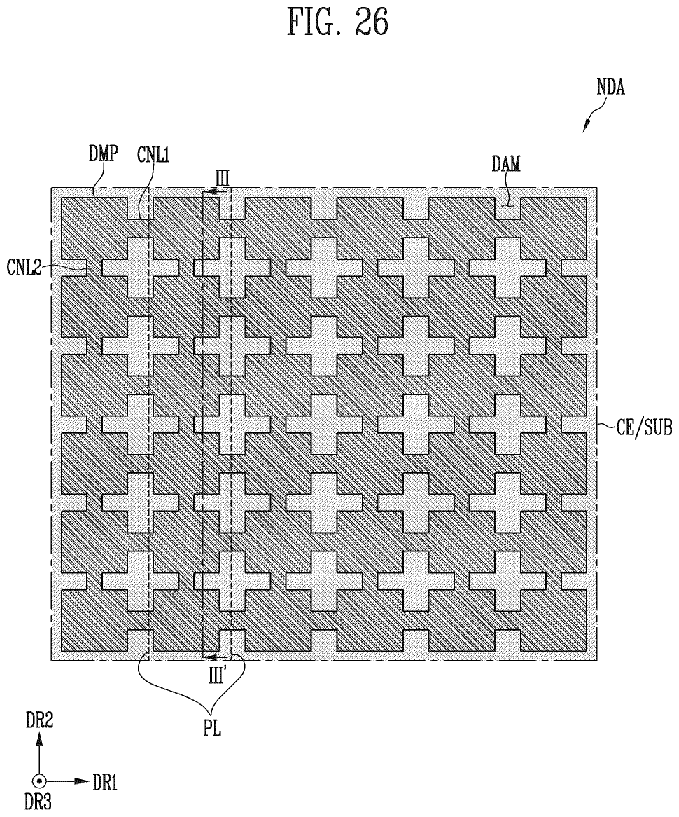

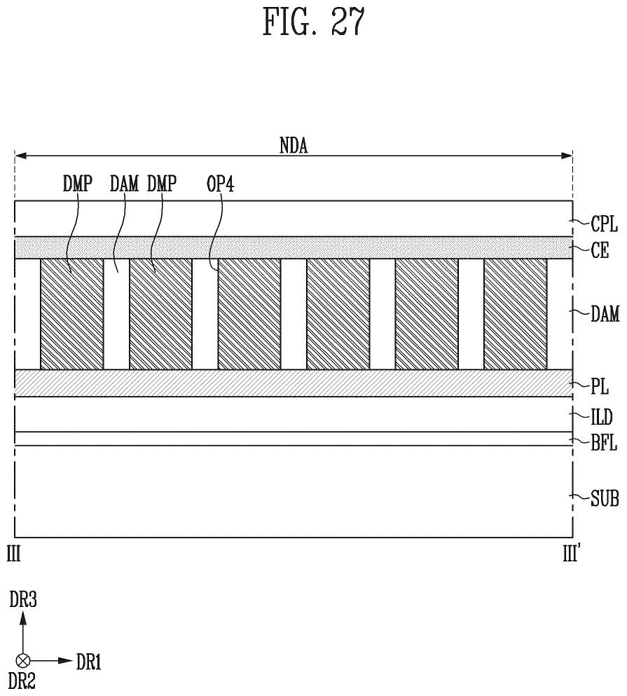

FIG. 26 is an enlarged schematic diagram corresponding to an EA area of FIG. 9, illustrating a portion of a non-display area NDA of a display device DD according to one or more embodiments, and FIG. 27 is a schematic cross-sectional diagram taken along the line III-III′ of FIG. 26.

Referring to FIG. 9, FIG. 26, and FIG. 27, a plurality of dummy patterns DMP may be arranged in the non-display area NDA. The dummy patterns DMP may have configurations that are arranged to secure a pattern density throughout the non-display area NDA.

When viewed on a plan, a plurality of dummy patterns DMP may be provided on the substrate SUB to be arranged in a matrix form along rows extending in the first direction DR1 and columns extending in the second direction DR2, but are not limited thereto.

The dummy patterns DMP adjacent in the first direction DR1 may be electrically connected through a first connection line CNL1. The dummy patterns DMP adjacent in the second direction DR2 may be electrically connected through a second connection line CNL2. The first connection line CNL1 may extend in the first direction DR1, and the second connection line CNL2 may extend in the second direction DR2. The dummy patterns DMP, the first connection line CNL1, and the second connection line CNL2 may be integrated to be connected to each other.

The dummy patterns DMP may form a mesh structure. The dummy patterns DMP may be electrically connected to the cathode electrode CE by direct contact with the cathode electrode CE. The dummy patterns DMP may reduce the resistance of the cathode electrode CE, thereby preventing or reducing the voltage drop of the cathode electrode CE.

The dummy patterns DMP may be formed of one of the conductive layers arranged on the pixel circuit layer (see “PCL” in FIG. 7) of the display area (see “DA” in FIG. 9). For example, the dummy patterns DMP may be formed of the conductive layer (or the source-drain conductive layer) including the first to third connection patterns CNP1 to CNP3 arranged in the pixel circuit layer PCL of the display area DA.

The dam structure DAM may be arranged between the dummy patterns DMP in the non-display area NDA. The dam structure DAM may be arranged on the power line PL in the non-display area NDA. Although not directly shown in the drawings, the dam structure DAM may be arranged on the inter-layer dielectric layer ILD in the non-display area NDA.

In one or more embodiments, the dam structure DAM may be formed of at least one of the insulating layers arranged in the pixel circuit layer PCL of the display area DA. For example, the dam structure DAM may be configured in a single layer structure formed by substantially the same process as the first passivation layer PSV1 arranged in the pixel circuit layer PCL of the display area DA, but the present disclosure is not limited thereto. According to one or more embodiments, the dam structure DAM may be formed by substantially the same process as the second passivation layer PSV2. The dam structure DAM may include a fourth opening OP4 that exposes one area of the configurations arranged on its bottom. For example, the dam structure DAM may include the fourth opening OP4 that exposes one area of the power line PL. A space between two adjacent dam structures DAM may be the fourth opening OP4.

The dummy patterns DMP may be arranged to be spaced and/or apart (e.g., spaced apart or separated) from the dam structure DAM. The dummy patterns DMP may be provided in the form of filling the fourth opening OP4 between the adjacent dam structures DAM. For example, each of the dummy patterns DMP may be provided in the form of filling the space surrounded by the adjacent dam structures DAM between adjacent dam structures DAM, e.g., the fourth opening OP4. In one or more embodiments, the dam structures DAM may define the formation position of the dummy patterns DMP. For example, the dummy pattern DMP may be formed within the fourth opening OP4 of the dam structure DAM. The dummy patterns DMP may be provided in the form of filling the inside the fourth opening OP4 of the dam structure DAM in the non-display area NDA through the CMP process. The upper surface of the dummy patterns DMP may be in a colinear position with the upper surface of the dam structure DAM in the first direction DR1.

According to one or more embodiments described herein, as the dam structure DAM that defines the formation position of the dummy pattern DMP in the non-display area NDA is formed of one of the insulating layers arranged in the pixel circuit layer PCL of the display area DA, the process for forming a separate structure defining the formation position of the dummy pattern DMP may not be provided, thereby simplifying the manufacturing process of the display device (see “DD” in FIG. 9).

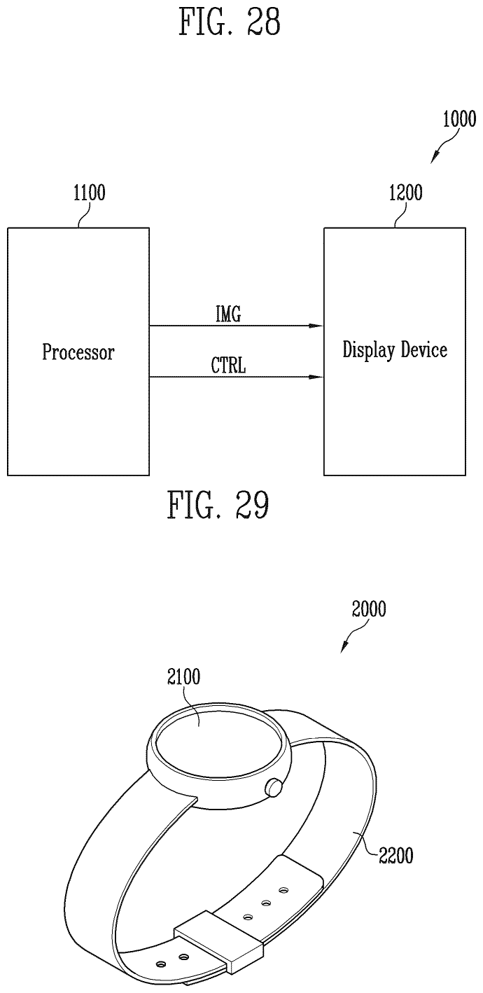

FIG. 28 is a schematic block diagram illustrating one or more embodiments of a display system 1000.

Referring to FIG. 28, the display system 1000 may include a processor 1100 and a display device 1200.

The processor 1100 may perform a variety of tasks and calculations. In one or more embodiments, the processor 1100 may include an application processor, a graphics processor, a microprocessor, and a central processing unit (CPU). The processor 1100 may be connected to other components of the display system 1000 through a bus system to control the components.

The processor 1100 may be to transmit image data IMG and control signals CTRL to the display device 1200. The display device 1200 may display images based on the image data IMG and the control signal CTRL. The display device 1200 may be configured as the display device DD described in reference to FIG. 1. In this case, the image data IMG and the control signal CTRL may be provided as the input image data IMG and the control signals CTRL of FIG. 1, respectively.

The display system 1000 may include a computing system that provides image display functions such as a smart watch, mobile phone, smart phone, portable computer, tablet personal computer (PC), watch phone, automotive display, smart glasses, portable multimedia player (PMP), navigator, and ultra mobile personal computer (UMPC). In some embodiments, the display system 1000 may include at least one of a head mounted display (HMD), a virtual reality (VR) device, a mixed reality (MR) device, and an augmented reality (AR) device.

FIG. 29 to FIG. 32 are schematic diagrams illustrating applied embodiments of a display system 1000 of FIG. 28.

Referring to FIG. 29, the display system 1000 of FIG. 28 may be applied to a smart watch 2000 including a display part 2100 and a strap part 2200.

The smart watch 2000 may be a wearable electronic device. For example, the smart watch 2000 may have a structure in which the strap part 2200 is mounted on the user's wrist. Here, the display part 2100 is applied with the display system 1000 and/or the display device 1200 so that image data including time information may be provided to a user.

Referring to FIG. 30, the display system 1000 of FIG. 28 may be applied to an automotive display system 3000. Here, the automotive display system 3000 may include a computing system that is equipped inside and/or outside a vehicle to provide image data.

For example, the display system 1000 and/or the display device 1200 shown in FIG. 28 may be applied to at least one of an infortainment panel 3100, a cluster 3200, a co-driver display 3300, a head-up display 3400, a side mirror display 3500, and a rear seat display 3600 that are provided inside the vehicle.

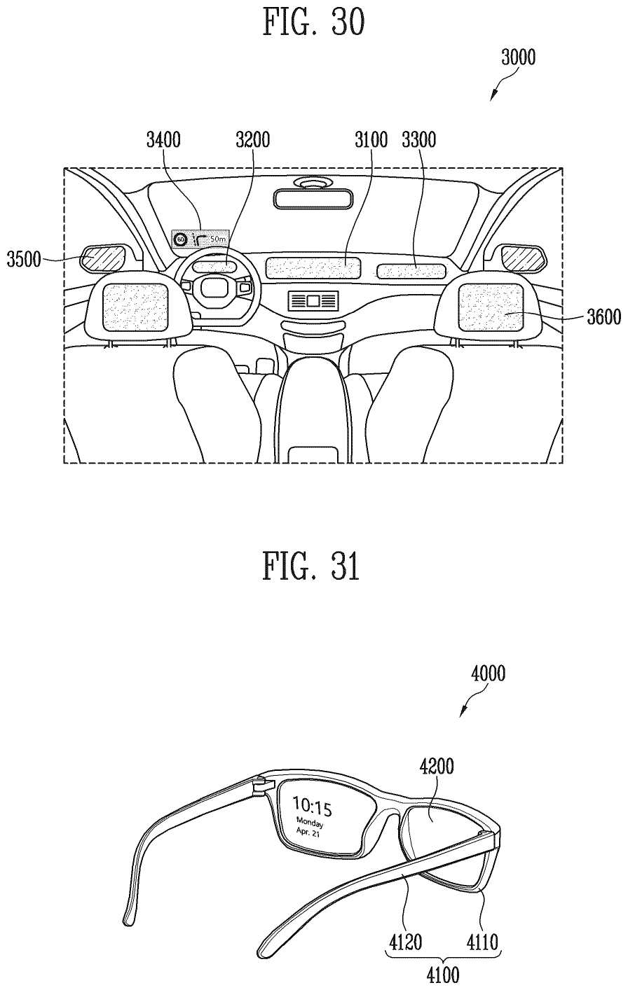

Referring to FIG. 31, the display system 1000 of FIG. 28 may be applied to smart glasses 4000. The smart glasses 4000 may be wearable electronic devices that are wearable on the user's head. For example, the smart glasses 4000 may be a wearable device for augmented reality.

The smart glasses 4000 may include a frame 4100 and a lens part 4200. The frame 4100 may include a housing 4110 supporting the lens part 4200 and a leg part 4120 for the user's wearing. The leg part 4120 may be connected to the housing 4110 by refers to of a hinge to be folded or unfolded with respect to the housing 4110.

The frame 4100 may be built in with a battery, touchpad, microphone, and camera. In some embodiments, the frame 4100 may be built in with a projector to output light and a processor to control the light signal.

The lens part 4200 may include an optical member that transmits or reflects light. For example, the lens part 4200 may include glass and transparent synthetic resins.

In order for the user's eyes to perceive the visual information, the lens part 4200 may reflect the image by the light signal emitted from the projector of the frame 4100 by the rear surface of the lens part 4200 (e.g., a surface opposite to (e.g., facing) the user's eyes). For example, the user may recognize visual information such as time and date displayed on the lens part 4200. Here, the projector and/or the lens part 4200 may be a type (kind) of display device. The display device 1200 may be applied to the projector and/or the lens part 4200.

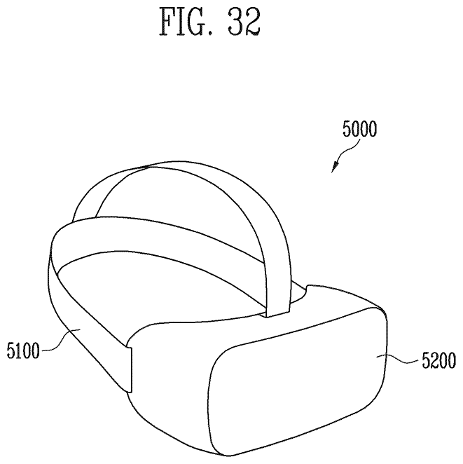

Referring to FIG. 32, the display system 1000 of FIG. 28 may be applied to a head-mounted display device 5000.

The head-mounted display device 5000 may be a wearable electronic device that is wearable on the user's head. For example, the head-mounted display device 5000 may be a wearable device for virtual reality or mixed reality.

The head-mounted display device 5000 may include a head-mounted band 5100 and a display device storage case 5200. The head-mounted band 5100 may be connected to the display device storage case 5200. The head-mounted band 5100 may include a horizontal band and/or a vertical band for fixing the head-mounted display device 5000 to the user's head. The horizontal band may be configured to be around (e.g., surround) the side of the user's head, and the vertical band may be configured to be around (e.g., surround) the upper part of the user's head. However, embodiments are not limited thereto. For example, the head-mounted band 5100 may be implemented in the form of glass frames and helmets.

The display device storage case 5200 may store the display system 1000 and/or the display device 1200.

Terms such as “substantially,” “about,” and “approximately” are used as relative terms and not as terms of degree, and are intended to account for the inherent deviations in measured or calculated values that would be recognized by those of ordinary skill in the art. They may be inclusive of the stated value and an acceptable range of deviation as determined by one of ordinary skill in the art, considering the limitations and error associated with measurement of that quantity. For example, “about” may refer to one or more standard deviations, or +30%, 20%, 10%, 5% of the stated value.

Numerical ranges disclosed herein include and are intended to disclose all subsumed sub-ranges of the same numerical precision. For example, a range of “1.0 to 10.0” includes all subranges having a minimum value equal to or greater than 1.0 and a maximum value equal to or less than 10.0, such as, for example, 2.4 to 7.6. Applicant therefore reserves the right to amend this specification, including the claims, to expressly recite any sub-range subsumed within the ranges expressly recited herein.

The display device, wearable electronic device, a device of manufacturing thereof, and/or any other relevant devices or components according to embodiments of the present disclosure described herein may be implemented utilizing any suitable hardware, firmware (e.g., an application-specific integrated circuit), software, or a combination of software, firmware, and hardware. For example, the one or more suitable components of the display and/or wearable electronic device may be formed on one integrated circuit (IC) chip or on separate IC chips. Further, the one or more suitable components of the display and/or wearable electronic device may be implemented on a flexible printed circuit film, a tape carrier package (TCP), a printed circuit board (PCB), or formed on one substrate. Further, the one or more suitable components of the display and/or wearable electronic device may be a process or thread, running on one or more processors, in one or more computing devices, executing computer program instructions and interacting with other system components for performing the one or more suitable functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of one or more suitable computing devices may be combined or integrated into a single computing device, or the functionality of a particular computing device may be distributed across one or more other computing devices without departing from the scope of the embodiments of the present disclosure.

In the context of the present application and unless otherwise defined, the terms “use,” “using,” and “used” may be considered synonymous with the terms “utilize,” “utilizing,” and “utilized,” respectively.

A person of ordinary skill in the art, in view of the present disclosure in its entirety, would appreciate that each suitable feature of the one or more suitable embodiments of the present disclosure may be combined or combined with each other, partially or entirely, and may be technically interlocked and operated in one or more suitable ways, and each embodiment may be implemented independently of each other or in conjunction with each other in any suitable manner unless otherwise stated or implied.

Although specific embodiments and applications have been described herein, one or more embodiments and variations may be derived from the preceding above description. Therefore, the technical scope of the present disclosure shall not be limited to one or more embodiments, but may extend to the appended claims, one or more suitable evident modifications, and equivalents thereof.

What is claimed is:

1. A display device comprising:
a substrate on which a display area and a non-display area are defined;
a pixel circuit layer on the substrate;
a plurality of light emitting elements on the pixel circuit layer in the display area and configured to emit light;
a first conductive pattern on the pixel circuit layer in the display area and spaced from each of the light emitting elements;
a plurality of dam structures on the substrate in the non-display area;
a second conductive pattern between two adjacent dam structures of the dam structures in the non-display area; and
an insulating layer on the light emitting elements, the first conductive pattern, the dam structures, and the second conductive pattern,
wherein the first conductive pattern and the second conductive pattern are in a same layer and comprise a same material,
the pixel circuit layer and each of the dam structures are each provided as multilayers comprising at least one conductive layer and at least one insulating layer, and
at least one of the multilayers of the pixel circuit layer and at least one of the multilayers of each of the dam structures are in a same layer.

2. The display device according to claim 1, wherein the first conductive pattern is filling a space surrounded by two adjacent light emitting elements of the light emitting elements and the insulating layer between the two adjacent light emitting elements, and
the second conductive pattern is filling a space surrounded by the two adjacent dam structures and the insulating layer between the two adjacent dam structures.

3. The display device according to claim 2, further comprising a cathode electrode that is on the insulating layer and electrically connected to the first conductive pattern, the second conductive pattern, and the light emitting elements.

4. The display device according to claim 3, wherein the cathode electrode is directly on the first conductive pattern and the second conductive pattern.

5. The display device according to claim 3, wherein the pixel circuit layer comprises:
an inter-layer dielectric layer on the substrate;
a first conductive layer on the inter-layer dielectric layer;
a first passivation layer on the first conductive layer and the inter-layer dielectric layer;
a second conductive layer on the first passivation layer; and
a second passivation layer on the second conductive layer and the first passivation layer, and
wherein each of the dam structures comprises a metal layer, a first insulating pattern, a dummy pattern, and a second insulating pattern that are sequentially laminated on the substrate.

6. The display device according to claim 5, wherein the metal layer is formed of the first conductive layer,
the first insulating pattern is formed of the first passivation layer, the dummy pattern is formed of the second conductive layer, and
the second insulating pattern is formed of the second passivation layer, and wherein the metal layer and the dummy pattern are electrically connected.

7. The display device according to claim 6, further comprising:
a power line provided in the non-display area and supplying a low potential voltage to the cathode electrode; and
a bridge pattern between the power line and the cathode electrode and electrically connecting the power line and the cathode electrode, wherein the power line is in a same layer as the metal layer and comprises a same material as the metal layer, and
the bridge pattern is provided in a same layer as the dummy pattern and comprises a same material as the dummy pattern.

8. The display device according to claim 7, wherein at least one of the dam structures is configured by comprising the power line, the first insulating pattern on the power line, the bridge pattern on the first insulating pattern, and a second insulating pattern on the bridge pattern.

9. The display device according to claim 8, wherein the insulating layer comprises a first opening exposing a portion of each of the light emitting elements and a second opening exposing a portion of the bridge pattern, and
the cathode electrode is electrically connected to the light emitting elements through the first opening and to the bridge pattern through the second opening.

10. The display device according to claim 9, wherein the insulating layer further comprises a third opening exposing a portion of the dummy pattern of each of the dam structures, and
the cathode electrode is electrically connected to the dummy pattern through the third opening.

11. The display device according to claim 8, wherein each of the dam structures further comprises a first layer, a second layer, and a third layer that are between the substrate and the metal layer, and
the first and third layers are inorganic insulating patterns, and the second layer is a conductive pattern.

12. The display device according to claim 3, further comprising an anode electrode that is on the pixel circuit layer in the display area, wherein each of the light emitting elements comprises a first end and a second end in a longitudinal direction, and
the first end is electrically connected to the anode electrode, and the second end is electrically connected to the cathode electrode.

13. The display device according to claim 12, wherein each of the light emitting elements comprises:
a first semiconductor layer positioned at the first end and electrically connected to the anode electrode;
a second semiconductor layer positioned at the second end and electrically connected to the cathode electrode; and
an active layer between the first semiconductor layer and the second semiconductor layer, and
wherein the first semiconductor layer is a p-type semiconductor layer doped with a p-type dopant, and the second semiconductor layer is an n-type semiconductor layer doped with an n-type dopant.

14. The display device according to claim 1, wherein the first conductive pattern and the second conductive pattern comprise copper.

15. A display device comprising:
a substrate on which a display area and a non-display area are defined;
a pixel circuit layer on the substrate;
a plurality of light emitting elements on the pixel circuit layer in the display area and configured to emit light;
a plurality of dam structures on the substrate in the non-display area;
a dummy pattern between two adjacent dam structures of the dam structures in the non-display area; and
a cathode electrode on the light emitting elements, the dam structures, and the dummy pattern,
wherein each of the dam structures is provided in a same layer as at least one insulating layer of the pixel circuit layer and comprises a same material as the at least one insulating layer, and
the dummy pattern is provided in a same layer as at least one conductive layer of the pixel circuit layer and comprises a same material as the one conductive layer.

16. The display device according to claim 15, wherein the dummy pattern is filling a space surrounded by the two adjacent dam structures and between the two adjacent dam structures.

17. The display device according to claim 15, wherein the pixel circuit layer comprises:
an inter-layer dielectric layer on the substrate;
a first conductive layer on the inter-layer dielectric layer;
a first passivation layer on the first conductive layer and the inter-layer dielectric layer; and
a second conductive layer on the first passivation layer, and
wherein each of the dam structures is an insulating pattern formed of the first passivation layer, and
the dummy pattern is formed of the second conductive layer.

18. The display device according to claim 17, further comprising:
a power line provided in the non-display area and supplying a low potential voltage to the cathode electrode, and
the cathode electrode is directly on the dummy pattern and electrically connected to the dummy pattern.

19. The display device according to claim 18, further comprising:
a first connection line in the non-display area and extending in a first direction; and
a second connection line in the non-display area and extending in a second direction intersecting the first direction,
wherein the dummy pattern is electrically connected to another dummy pattern adjacent in the first direction through the first connection line,
the dummy pattern is electrically connected to another dummy pattern adjacent in the second direction through the second connection line, and
the dummy pattern, the first connection line, and the second connection line are connected to each other to have a mesh structure.

20. A wearable electronic device comprising:
a display panel; and
a lens on the display panel,
wherein the display panel comprises:
a substrate on which a display area and a non-display area are defined;
a pixel circuit layer on the substrate;
a plurality of light emitting elements on the pixel circuit layer in the display area and configured to emit light;
a first conductive pattern on the pixel circuit layer in the display area and to be spaced apart from each of the light emitting elements;
a plurality of dam structures on the substrate in the non-display area;
a second conductive pattern between two adjacent dam structures of the dam structures in the non-display area; and
an insulating layer on the plurality of light emitting elements, the first conductive pattern, the dam structures, and the second conductive pattern,
wherein the first conductive pattern and the second conductive pattern are in a same layer and comprise a same material,
the pixel circuit layer and each of the dam structures are each provided as multilayers comprising at least one conductive layer and at least one insulating layer, and
at least one of the multilayers of the pixel circuit layer and at least one of the multilayers of each of the dam structures are provided in a same layer.
